(19) United States
(12) Patent Application Publication
(10) Pub. No.: US 2025/0301868 A1
(43) Pub. Date: Sep. 25, 2025

(54) DISPLAY DEVICE AND ELECTRONIC DEVICE HAVING THE SAME

(71) Applicant: Samsung Display Co., LTD., Yongin-si (KR)

(72) Inventors: Hee Rim SONG, Yongin-si (KR); So Il YOON, Yongin-si (KR); Cheol Gon LEE, Yongin-si (KR); Mu Kyung JEON, Yongin-si (KR)

(21) Appl. No.: 18/977,771

(22) Filed: Dec. 11, 2024

(30) Foreign Application Priority Data
Mar. 19, 2024 (KR) 10-2024-0037713

(51) Int. Cl. H10K 59/131; H10K 39/34

(52) U.S. Cl. CPC H10K 59/131; H10K 39/34

(57) ABSTRACT

Provided is an electronic device including a processor configure to provide input image data to a display device configured to display an image based on the input image data, and a power supply configured to supply power to the display device, wherein the display device includes a pixel including a light-emitting element, and a photo sensor including a light-receiving element at a same layer as the light-emitting element, and including a first sensor transistor configured to control a current flowing to a readout line in response to a voltage of one electrode of the light-receiving element, a second sensor transistor electrically connected between the first sensor transistor and the readout line, and including first and second sub-transistors connected in series, and a first capacitor between a first middle node, to which the first and second sub-transistors are connected, and a power line.

### CROSS-REFERENCE TO RELATED APPLICATION

The present application claims priority to, and the benefit of, Korean Patent Application No. 10-2024-0037713 filed in the Korean Intellectual Property Office on Mar. 19, 2024, the entire disclosure of which is incorporated herein by reference.

### BACKGROUND

### 1. Field

The present disclosure relates to a display device including a photo sensor, and an electronic device having the same.

### 2. Description of the Related Art

As information technology develops, the importance of display devices, which are a connection medium between users and information, is emerging. Accordingly, the use of display devices, such as a liquid crystal display device, an organic light-emitting display device, and the like has been increasing. In addition, the display device may sense the user's fingerprint using a photo sensor and perform a user authentication function.

### SUMMARY

An aspect of the present disclosure provides a display device that may improve the performance of a photo sensor.

Another aspect of the present disclosure provides an electronic device having the display device.

Embodiments of the present disclosure provide a display device including a pixel including a light-emitting element, and a photo sensor including a light-receiving element at a same layer as the light-emitting element, a first sensor transistor configured to control a current flowing to a readout line in response to a voltage of one electrode of the light-receiving element, a second sensor transistor electrically connected between the first sensor transistor and the readout line, and including first and second sub-transistors connected in series, and a first capacitor between a first middle node, to which the first and second sub-transistors are connected, and a power line.

A constant voltage may be configured to be applied to the power line.

The pixel may further include a switching transistor electrically connected between the power line and an anode electrode of the light-emitting element.

The pixel may further include a first transistor electrically connected between a first power line and the light-emitting element, and a second transistor electrically connected between a data line and the first transistor, and wherein a gate electrode of the second transistor and a gate electrode of the first sensor transistor are electrically connected to a first scan line.

In a cross-sectional view, the photo sensor may further include a semiconductor layer of the first and second sub-transistors, a gate electrode above the semiconductor layer, an insulating layer covering the gate electrode, a capacitor electrode above the insulating layer, and at least one insulating layer above the capacitor electrode, wherein the power line is above the at least one insulating layer, and contacts the capacitor electrode through a contact hole, and wherein the first capacitor includes the capacitor electrode and the semiconductor layer.

In a plan view, the power line may extend in a first direction between the first sensor transistor and the second sensor transistor, and partially protrudes in a second direction to overlap the capacitor electrode.

The photo sensor may further include a third sensor transistor electrically connected between a reference power line and the one electrode of the light-receiving element.

The first sensor transistor and the second sensor transistor may include a silicon semiconductor, wherein the third sensor transistor includes an oxide semiconductor.

One electrode of the first sensor transistor may be electrically connected to the power line, wherein the power line and the reference power line are configured to receive different voltages.

The power line and the reference power line may be configured to receive a same voltage.

The light-emitting element may be electrically connected between a first power line and a second power line, wherein the power line is configured to receive a same voltage as the first power line or the second power line.

The photo sensor may further include a third sensor transistor that is electrically connected between a reference power line and the one electrode of the light-receiving element and includes third and fourth sub-transistors connected in series, and a second capacitor between a second middle node to which the third and fourth sub-transistors are connected and a first power line.

The power line and the first power line may be configured to receive a same constant voltage.

The pixel may further include a first transistor connected between the first power line and the light-emitting element, and a storage capacitor electrically connected between a gate electrode of the first transistor and the first power line, wherein one electrode of the second capacitor and one electrode of the storage capacitor are integral.

In a plan view, the one electrode of the storage capacitor may overlap a first semiconductor pattern of the first transistor, wherein the one electrode of the second capacitor has a size that is smaller than that of the one electrode of the storage capacitor, and protrudes from the one electrode of the storage capacitor to overlap a third semiconductor pattern of the third sensor transistor.

The pixel may further include a third transistor electrically connected between one electrode and a gate electrode of the first transistor, wherein, in a plan view, one electrode of the first capacitor overlaps a second semiconductor pattern of the second sensor transistor, and protrudes toward the third transistor to overlap a semiconductor pattern of the third transistor.

Embodiments of the present disclosure provide a display device including a pixel including a light-emitting element, and a photo sensor including a light-receiving element at a same layer as the light-emitting element, a first sensor transistor configured to control a current flowing to a readout line in response to a voltage of one electrode of the light-receiving element, a second sensor transistor electrically connected between the first sensor transistor and the readout line, a third sensor transistor electrically connected between a reference power line and the one electrode of the light-receiving element, and including third and fourth sub-transistors connected in series, and a second capacitor between a second middle node, to which the third and fourth sub-transistors are connected, and a first power line.

The power line and the first power line may be configured to receive a same constant voltage.

The pixel may further include a first transistor connected between the first power line and the light-emitting element, and a storage capacitor electrically connected between a gate electrode of the first transistor and the first power line, wherein one electrode of the second capacitor and one electrode of the storage capacitor are integral.

Embodiments of the present disclosure provide an electronic device including a processor configure to provide input image data to a display device configured to display an image based on the input image data, and a power supply configured to supply power to the display device, wherein the display device includes a pixel including a light-emitting element, and a photo sensor including a light-receiving element at a same layer as the light-emitting element, and including a first sensor transistor configured to control a current flowing to a readout line in response to a voltage of one electrode of the light-receiving element, a second sensor transistor electrically connected between the first sensor transistor and the readout line, and including first and second sub-transistors connected in series, and a first capacitor between a first middle node, to which the first and second sub-transistors are connected, and a power line.

In the display device and the electronic device according to the embodiments of the present disclosure, the sensor transistor in the photo sensor may be implemented as a dual-gate transistor, and a capacitor may be connected between a middle node of the sensor transistor and a constant voltage wire. Accordingly, a leakage current through the sensor transistor may be reduced or minimized, and sensing sensitivity of the photo sensor may be improved.

Aspects of embodiments of the present disclosure are not limited by what is illustrated in the above, and more various aspects are included in the present specification.

### BRIEF DESCRIPTION OF THE DRAWINGS

FIG. 1 illustrates a block diagram of a display device according to embodiments of the present disclosure.

FIG. 2 illustrates a block diagram of one or more embodiments of the display device of FIG. 1.

FIG. 3 illustrates an example of disposition of backplane circuits in a display area of a display panel included in the display device of FIG. 2.

FIG. 4 illustrates an example of a display area of a display panel included in the display device of FIG. 2.

FIG. 5 illustrates a circuit diagram of an example of a pixel and a photo sensor included in the display area of FIG. 4.

FIG. 6 illustrates a waveform diagram of one or more embodiments of an operation of the pixel and the photo sensor of FIG. 5.

FIG. 7A, FIG. 7B, and FIG. 7C illustrate top plan views of one or more embodiments of the display area of FIG. 4.

FIG. 8 illustrates a cross-sectional view of one or more embodiments of the display area of FIG. 4.

FIG. 9 illustrates a top plan view of one or more embodiments of area BB of FIG. 7A.

FIG. 10 illustrates a circuit diagram of one or more embodiments of a pixel and a photo sensor included in the display area of FIG. 4.

FIG. 11 illustrates a top plan view of one or more embodiments of a display area of FIG. 4.

FIG. 12 illustrates a circuit diagram of one or more other embodiments of a pixel and a photo sensor included in the display area of FIG. 4.

FIG. 13 illustrates a circuit diagram of one or more other embodiments of a pixel and a photo sensor included in the display area of FIG. 4.

FIG. 14A, FIG. 14B, and FIG. 14C illustrate top plan views of one or more embodiments of the display area of FIG. 4.

FIG. 15 illustrates a cross-sectional view of one or more embodiments of the display area of FIG. 4.

FIG. 16A and FIG. 16B illustrate plan views of one or more embodiments of area CC of FIG. 14C.

FIG. 17 illustrates a circuit diagram of one or more other embodiments of a pixel and a photo sensor included in the display area of FIG. 4.

FIG. 18 illustrates a block diagram of an electronic device according to embodiments.

FIG. 19 illustrates an example in which the electronic device of FIG. 18 is implemented as a smart phone.

FIG. 20 illustrates an example in which the electronic device of FIG. 18 is implemented as a tablet PC.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

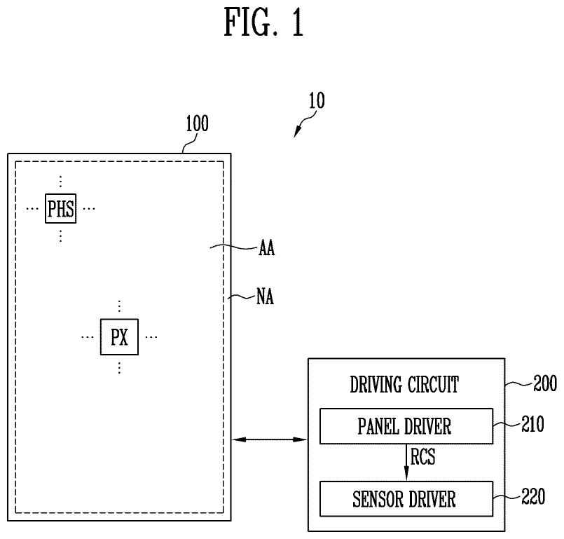

FIG. 1 illustrates a block diagram of a display device according to embodiments of the present disclosure.

Referring to FIG. 1, a display device 10 may include a display panel 100 and a driving circuit 200. The driving circuit 200 may include a panel driver 210 and a sensor driver 220.

The display device 10 may be implemented as a self-light-emitting display device including a plurality of self-emitting elements. For example, display device 10 may be an organic light-emitting display device including organic light-emitting elements. However, this is an example, and the display device 10 may be implemented as a display device including inorganic light-emitting elements, a display device including light-emitting elements configured of a combination of inorganic and organic materials, or a display device that displays an image with a quantum dot.

The display device 10 may be a flat panel display, a flexible display device, a curved display device, a foldable display device, a bendable display device, or a rollable display device. In addition, the display device may be applied to a transparent display device, a head-mounted display device, a wearable display device, and the like.

The display panel 100 includes a display area AA and a non-display area NA. The display area AA may be an area in which a pixel PX is provided. The pixel PX may be referred to as a sub-pixel or a light-emitting pixel. The pixel PX may include at least one light-emitting element. For example, the light-emitting element may include a light-emitting layer (for example, an organic light-emitting layer). A portion emitted by the light-emitting element may be defined as a light-emitting area. The display device 10 may display an image in the display area AA by driving the pixels PX in response to image data.

The non-display area NA may be an area provided around the display area AA. The non-display area NA may comprehensively refer to the remaining area excluding the display area AA on the display panel 100. For example, the non-display area NA may include a wire area, a pad area, and various dummy areas.

The display area AA may include a photo sensor PHS. The photo sensor PHS may be referred to as a sensor pixel. The photo sensor PHS may include a light-receiving element including a light-receiving layer. In the display area AA, the light-receiving layer of the light-receiving element is located on the same layer as the light-emitting layer of the light-emitting element, and may be spaced apart from the light- emitting layer in a plan view.

A plurality of photo sensors PHS may be distributed while spaced apart from each other throughout the entire area of the display area AA. However, this is an example, and only a portion of the display area AA is set as a sensing area (e.g., a predetermined sensing area), and the photo sensors PHS may be provided in the corresponding sensing area. In addition, at least a portion of the non-display area NA may also include a photo sensor PHS.

The photo sensor PHS may detect that light emitted from a light source (for example, a light-emitting element of the pixel PX) is reflected by an external object (for example, a user's finger). For example, a user's fingerprint may be detected through the photo sensor PHS. Hereinafter, the present disclosure will be described using the light sensor PHS as an example for fingerprint detection, but in various embodiments, the light sensor PHS may detect various biometric information, such as iris, veins, and the like.

The driving circuit 200 may include the panel driver 210 and the sensor driver 220. The display device 10 may include the panel driver 210 and the sensor driver 220. For example, the panel driver 210 and the sensor driver 220 may be implemented as independent integrated circuits, or the driving circuit 200 may be implemented as a single integrated circuit. For example, at least a portion of the sensor driver 220 may be included in the panel driver 210, or may operate in conjunction with the panel driver 210.

The panel driver 210 may scan the pixel PX of the display area AA, and may supply a data signal corresponding to image data (or an image) to the pixel PX. The display panel 100 may display an image corresponding to the data signal.

The panel driver 210 may supply a driving signal for light sensing (for example, fingerprint sensing) to the pixel PX. The driving signal may be provided so that the pixel PX emits light and operates as a light source for the light sensor PHS. The panel driver 210 may supply the driving signal for light sensing and/or other driving signals to the light sensor PHS. However, this is an example, and the driving signals for light sensing may be provided by the sensor driver 220.

The sensor driver 220 may detect biometric information, such as a user's fingerprint based on a sensing signal received from the light sensor PHS. The sensor driver 220 may supply the driving signals to the light sensor PHS and/or the pixel PX.

The panel driver 210 may provide a readout control signal RCS to the sensor driver 220, and the sensor driver 220 may read out (or sample) a detection signal in conjunction with the panel driver 210 based on the readout control signal RCS. For example, the sensor driver 220 may read out or sample the detection signal in units of at least one pixel row (or horizontal line) in response to the readout control signal RCS.

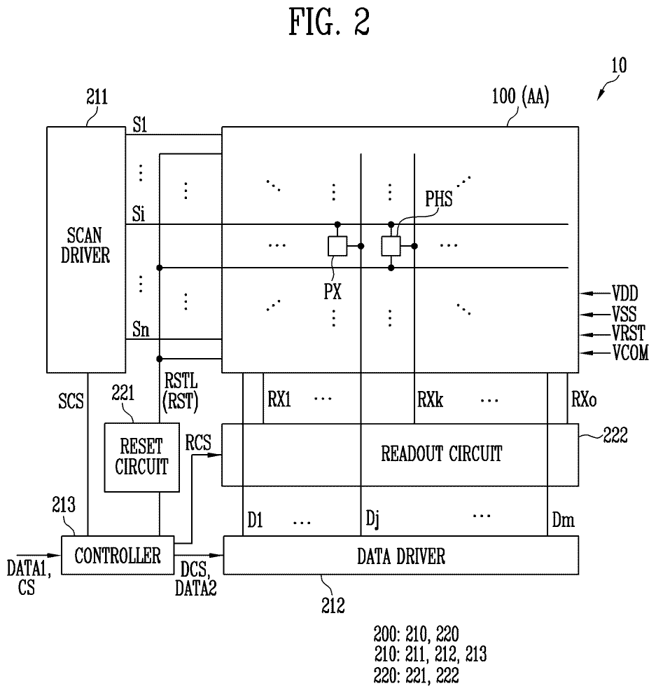

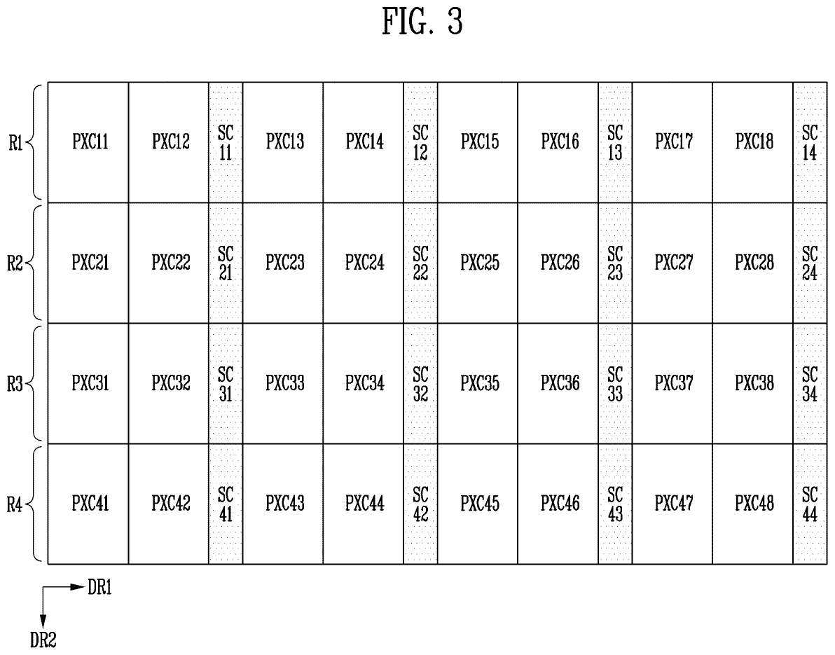

FIG. 2 illustrates a block diagram of one or more embodiments of the display device of FIG. 1.

Referring to FIG. 1 and FIG. 2, the display panel 100 may include signal lines, the pixel PX, and the light sensor PHS. The signal lines may include scan lines S1 to Sn, data lines D1 to Dm, readout lines RX1 to RXo, and a reset control line RSTL (or reset line). Here, n, m, and o may each be a natural number.

The pixel PX may be located or positioned in an area (for example, a pixel area) partitioned by the scan lines S1 to Sn and the data lines D1 to Dm. The light sensor PXL may be located or positioned in an area partitioned by the scan lines S1 to Sn and the readout lines RX1 to RXo. The pixel PX and the light sensor PHS may be located in a two-dimensional array in the display area AA of the display panel 100, but are not limited thereto.

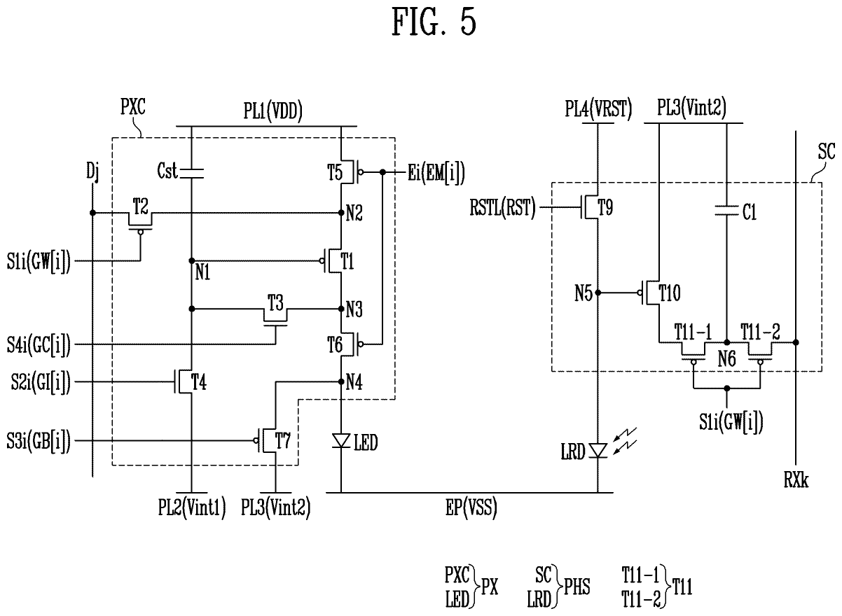

The pixel PX may be electrically connected to at least one of the scan lines S1 to Sn and/or one of the data lines D1 to Dm. The light sensor PHS may be electrically connected to one of the scan lines S1 to Sn, one of the readout lines RX1 to RXo, and the reset control line RSTL. The connection configuration between the pixel PX, the light sensor PHS, and the signal lines will be described later with reference to FIG. 5.

Power voltages VDD, VSS, VRST, and VCOM suitable for driving the pixel PX and the photo sensor PHS may be provided in the display panel 100. The power voltages VDD, VSS, VRST, and VCOM may be provided from a power supply. The power supply may be implemented as a power management integrated circuit.

The driving circuit 200 may include a scan driver 211 (or a gate driver), a data driver 212 (or a source driver), a controller 213 (or a timing controller or a second processor), a reset circuit 221 (or a reset portion), and a readout circuit 222 (or a readout portion). For example, the scan driver 211, the data driver 212, and the controller 213 may be included in the panel driver 210, and the reset circuit 221 and the readout circuit 222 may be included in the sensor driver 220, but are not limited thereto. For example, the reset circuit 221 may be included in the panel driver 210.

The scan driver 211 may be electrically connected to the pixel PX and to the light sensor PHS through the scan lines S1 to Sn. The scan driver 211 may generate scan signals based on a scan control signal SCS (or gate control signal), and may provide the scan signals to the scan lines S1 to SLn. Here, the scan control signal SCS may include a start signal, clock signals, and the like, and may be provided from the controller 213 to the scan driver 211. For example, the scan driver 211 may be implemented as a shift register that generates and outputs the scan signals by sequentially shifting the start signal in the form of pulses using the clock signals. That is, the scan driver 211 may selectively drive the pixel PX and the light sensor PHS while scanning the display panel 100.

The scan driver 211 may be formed with the pixel PXL on the display panel 100. However, the scan driver 211 is not limited thereto, and for example, the scan driver 211 may be implemented as an integrated circuit.

The pixel PX that is selectively driven by the scan driver 211 may emit light with luminance corresponding to the data signal provided to the data line. The light sensor PHS that is selectively driven by the scan driver 211 may output an electrical signal (that is, a detection signal, for example, current/voltage) corresponding to the detected light to the readout line. For example, the pixel PX selectively driven through the i-th scan line Si may emit light with luminance corresponding to the data signal provided to the j-th data line Dj (wherein i and j are natural numbers). For example, the light sensor PHS selectively driven through the i-th scan line Si may output an electrical signal corresponding to the detected light to the k-th readout line RXk (wherein k is a natural number).

The data driver 212 may generate a data signal (or data voltage) based on image data DATA2 and a data control signal DCS provided from the controller 213, and may transmit the data signal to the display panel 100 (or the pixel PX) through the data lines D1 to Dm. Here, the data control signal DCS may be a signal that controls an operation of the data driver 212, and may include a data enable signal (or load signal), a horizontal start signal, and a data clock signal that direct the output of a valid data signal. For example, the data driver 212 may include: a shift register that generates a sampling signal by shifting the horizontal start signal in synchronization with the data clock signal; a latch that latches the image data DATA2 in response to the sampling signal; a digital-to-analog converter (or decoder) that converts the latched image data (for example, data in digital form) into a data signal in analog form; and a buffer (or amplifier) that outputs the data signal to the data line (for example, the j-th data line Dj).

The controller 213 may receive input image data DATA1 and a control signal CS from an external device (for example, a graphics processor, an application processor, or a first processor), may generate the scan control signal SCS and the data control signal DCS based on the control signal CS, and may convert the input image data DATA1 to generate the image data DATA2. The control signal CS may include a vertical synchronization signal, a horizontal synchronization signal, a reference clock signal, and the like. The vertical synchronization signal may indicate the start of frame data (that is, data corresponding to a frame period in which one frame image is displayed), and the horizontal synchronization signal may indicate the start of a data row (that is, one of a plurality of data rows included in the frame data). The controller 213 may convert the input image data DATA1 into the image data DATA2 having a format that matches the pixel array in the display panel 100.

In addition, the controller 213 may generate a reset control signal and a readout control signal RCS based on the control signal CS.

The reset circuit 221 may be connected to the light sensor PHS provided in the display panel 100 through the reset control line RSTL. For example, the reset circuit 221 may be commonly connected to all light sensors PHS provided in the display panel 100 through one reset control line RSTL. The reset circuit 221 may concurrently or substantially simultaneously provide a reset signal RST (or reset control signal) to all light sensors PHS in response to the reset control signal. Here, the reset signal RST may be a control signal for providing the reset voltage VRST to the light sensor PHS. Because the reset signal RST is concurrently or substantially simultaneously provided to all light sensors PHS, the reset signal RST may be referred to as a global reset signal. However, the reset circuit 221 is not limited thereto. For example, the reset circuit 221 may be implemented similarly to the scan driver 211 to sequentially provide a reset signal to the light sensor PHS.

The readout circuit 222 may receive a detection signal from the light sensor PHS through the readout lines RX1 to RXo, and may perform signal processing on the detection signal. For example, the readout circuit 222 may convert an analog detection signal into a digital signal (or digital value).

The readout detection signals may be provided to an external device (for example, an application processor) as a piece of sensing data (or biometric information), and biometric authentication (for example, fingerprint authentication) may be performed based on the sensing data. Alternatively, the readout detection signals may be provided to the controller 213, and the controller 213 may perform biometric authentication.

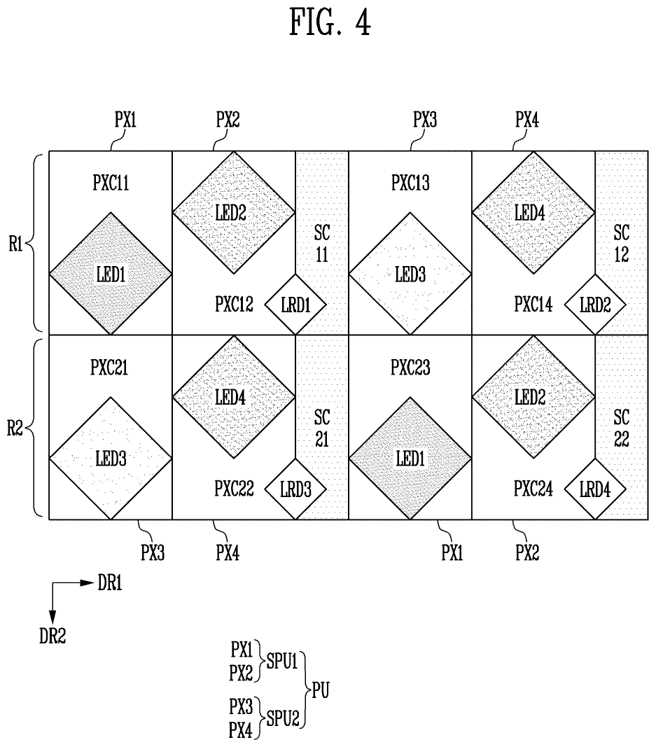

FIG. 3 illustrates an example of disposition of backplane circuits in a display area of a display panel included in the display device of FIG. 2. FIG. 4 illustrates an example of a display area of a display panel included in the display device of FIG. 2.

Referring to FIG. 1 to FIG. 4, pixels PX1 to PX4 and a plurality of light sensors PHS may be arranged in the display area AA of the display panel 100.

The display area AA may be divided into pixel rows R1 to R4. Each of the pixel rows R1 to R4 may extend in the first direction DR1, and may be arranged in the second direction DR2. Each of the pixel rows R1 to R4 may include the pixels PX1 to PX4. Each of the pixels PX1 to PX4 may include one of pixel circuits PXC11 to PXC18, PXC21 to PXC28, PXC31 to PXC38, and PXC41 to PXC48 and one of light-emitting elements LED1 to LED4.

The first pixel PX1, the second pixel PX2, and the third pixel PX3 may emit first color light, second color light, and third color light, respectively. The first color light, the second color light, and the third color light are different color light, and each of the first color light, the second color light, and the third color light may be one of red, green, and blue. The fourth pixel PX4 may emit the same color light as the second pixel PX2. For example, the first light-emitting element LED1 may emit the first color light, the second light-emitting element LED2 and the fourth light-emitting element LED4 may emit the second color light, and the third light-emitting element LED3 may emit the third color light.

In FIG. 4, each of the light-emitting elements LED1 to LED4 may be understood as a light-emitting area corresponding to a light-emitting layer. However, this is only for better understanding and ease of description, and the color of light emitted by each of the light-emitting elements LED1 to LED4, and the position, area, and shape of each of the light-emitting elements LED1 to LED4 are not limited thereto.

In each of the odd-numbered pixel rows, including the first pixel row R1 (or the first horizontal line) and the third pixel row R3 (or the third horizontal line), the pixels PX1 to PX4 may be arranged in the first direction DR1 in the order of the first pixel PX1 emitting red light, the second pixel PX2 emitting green light, the third pixel PX3 emitting blue light, and the fourth pixel PX4 emitting green light.

In each of the even-numbered pixel rows, including the second pixel row R2 (or the second horizontal line) and the fourth pixel row R4 (or the fourth horizontal line), the pixels PX1 to PX4 may be arranged in the first direction DR1 in the order of the third pixel PX3, the fourth pixel PX4, the first pixel PX1, and the second pixel PX2.

The first pixel PX1 and the second pixel PX2 may configure a first sub-pixel unit SPU1, and the third pixel PX3 and the fourth pixel PX4 may configure a second sub-pixel unit SPU2. Therefore, the first sub-pixel unit SPU1 and the second sub-pixel unit SPU2 may be alternately located in the odd-numbered pixel rows R1 and R3, and the second sub-pixel unit SPU2 and the first sub-pixel unit SPU1 may be alternately located in the even-numbered pixel rows R2 and R4 in a pattern opposite to the odd-numbered pixel rows R1 and R3.

It may be understood that the first and second sub-pixel units (e.g., predetermined first and second sub-pixel units) SPU1 and SPU2 adjacent to each other configure one pixel unit PU. For example, FIG. 4 illustrates the pixel unit PU of each of the first pixel row R1 and the second pixel row R2. However, this is an example, and the arrangement of the pixels is not limited thereto.

In the first pixel row R1, the pixel circuits PXC11 to PXC18 respectively corresponding to the pixels PX1 to PX4 of the first pixel row R1 may be arranged in the first direction DR1. In the second pixel row R2, the pixel circuits PXC21 to PXC28 respectively corresponding to the pixels PX1 to PX4 of the second pixel row R2 may be arranged in the first direction DR1. Similarly, in the third and fourth pixel rows R3 and R4, the pixel circuits PXC31 to PXC38 and PXC41 to PXC48 respectively corresponding to the pixels PX1 to PX4 of the third and fourth pixel rows R3 and R4 may be arranged in the first direction DR1.

In FIG. 3, the first, second, third, and fourth pixel circuits PXC11, PXC12, PXC13, and PXC14 of the first pixel row R1 may be included in one pixel unit PU, and the fifth, sixth, seventh, and eighth pixel circuits PXC15, PXC16, PXC17, and PXC18 of the first pixel row R1 may be included in another pixel unit PU.

Similarly, the first to fourth pixel circuits PXC21 to PXC24 of the second pixel row R2, the fifth to eighth pixel circuits PXC25 to PXC28 of the second pixel row R2, the first to fourth pixel circuits PXC31 to PXC34 of the third pixel row R3, the fifth to eighth pixel circuits PXC35 to PXC38 of the third pixel row R3, the first to fourth pixel circuits PXC41 to PXC44 of the fourth pixel row R4, and the fifth to eighth pixel circuits PXC45 to PXC48 of the fourth pixel row R4 may also be included in different pixel units PU, respectively.

The pixel rows R1 to R4 may include light-receiving elements LRD1 to LRD4, respectively. The light-receiving elements LRD1 to LRD4 may be understood as light-receiving areas respectively corresponding to the light-receiving layers. However, this is only for better understanding and ease of description, and the position, area, and shape of the light-receiving elements LRD1 to LRD4 are not limited thereto.

The light-receiving elements LRD1 and LRD2 of the first pixel row R1 may overlap at least some of the pixel circuits PXC11 to PXC14 of the first pixel row R1 and the sensor circuits SC11 and SC12 of the first pixel row R1, respectively. The light-receiving elements LRD3 and LRD4 of the second pixel row R2 may overlap at least some of the pixel circuits PXC21 to PXC24 of the second pixel row R2 and the sensor circuits SC21 and SC22 of the second pixel row R2, respectively.

The first light-receiving element LRD1 may overlap at least a portion of the first sensor circuit SC11 of the first pixel row R1, and the third light-receiving element LRD3 may overlap at least a portion of the first sensor circuit SC21 of the second pixel row R2.

In addition, referring to FIG. 2 and FIG. 3 together, the second light-receiving element LRD2 may overlap at least a portion of the second sensor circuit SC12 of the first pixel row R1, and the fourth light-receiving element LRD4 may overlap at least a portion of the second sensor circuit SC22 of the second pixel row R2.

The light-receiving elements LRD1 to LRD4 may be formed in the display area AA in an arrangement as shown in FIG. 4.

The sensor circuits SC11 to SC44 may be connected to corresponding light-receiving elements. For example, the first sensor circuit SC11 of the first pixel row R1 may be connected to the first light-receiving element LRD1, and the first sensor circuit SC11 and the first light-receiving element LRD1 may form one light sensor PHS. Similarly, the second sensor circuit SC12 of the first pixel row R1 may be connected to the second light-receiving element LRD2, the first sensor circuit SC21 of the second pixel row R2 may be connected to the third light-receiving element LRD3, and the second sensor circuit SC22 of the second pixel row R2 may be connected to the fourth light-receiving element LRD4. However, the present disclosure is not limited thereto. For example, only some of the sensor circuits SC11 to SC44 may be provided, and some thereof may be connected to a plurality of light-receiving elements.

The first sensor circuit SC11 of the first pixel row R1 may be located between the first sub-pixel unit SPU1 and the second sub-pixel unit SPU2 included in the pixel unit PU. For example, the first and second pixel circuits PXC11 and PXC12 of the first pixel row R1 may be included in the first sub-pixel unit SPU1, and the third and fourth pixel circuits PXC13 and PXC14 of the first pixel row R1 may be included in the second sub-pixel unit SPU2. Accordingly, at least two pixel circuits (for example, PXC13 and PXC14) may be located between the first sensor circuit SC11 and the second sensor circuit SC12 adjacent to each other in the first pixel row R1.

The second sensor circuit SC12 of the first pixel row R1, the first sensor circuit SC21 of the second pixel row R2, and the second sensor circuit SC22 of the second pixel row R2 may be located between respective ones of the first sub-pixel unit SPU1 and the second sub-pixel unit SPU2, similar to the first sensor circuit SC11 of the first pixel row R1.

FIG. 5 illustrates a circuit diagram of an example of a pixel and a photo sensor included in the display area of FIG. 4. For better understanding and ease of description, FIG. 5 illustrates the pixel PX located on an i-th horizontal line (or an i-th pixel row) and connected to a j-th data line Dj. The i-th scan lines S1i to S4i may be included in the scan lines S1 to Sn or i-th scan line Si of FIG. 2.

Hereinafter, the term “connected” or “coupled” may refer to an electrical connection based on a circuit. In addition, the term “connected” or “coupled” may refer to a physical connection (that is, contact) as well as an electrical connection in a plan view and cross-sectional view.

Referring to FIG. 1 to FIG. 5, the pixel PX and the light sensor PHS may be located in the i-th horizontal line.

The pixel PX may include a light-emitting element LED and a pixel circuit PXC. The pixel circuit PXC may include first, second, third, fourth, fifth, sixth, and seventh transistors T1, T2, T3, T4, T5, T6, and T7, and a storage capacitor Cst.

The first transistor T1 (or driving transistor) may be electrically connected between a first power line PL1 and a first electrode of the light-emitting element LED. The first transistor T1 may include a gate electrode connected to a first node N1. The first transistor T1 may control an amount of current (or the driving current) flowing from the first power line PL1 to an electrode EP (or power line) via the light-emitting element LED based on a voltage of the first node N1. A first power voltage VDD may be provided to the first power line PL1, a second power voltage VSS may be provided to the electrode EP, and the first power voltage VDD may be a higher voltage than the second power voltage VSS. For example, the first power voltage VDD may be about 4.6 V, and the second power voltage VSS may be about −2.5 V.

The second transistor T2 may be connected between a j-th data line Dj and a second node N2. A gate electrode of the second transistor T2 may be connected to a (1i)-th scan line S1i (or first scan line). The second transistor T2 may be turned on when the first scan signal GW[i] (for example, low-level first scan signal) is supplied to the (1i)-th scan line S1i to connect the j-th data line Dj and the second node N2. When each of the first transistor T1 and the third transistor T3 is turned on, the second transistor T2 may transmit a data signal of the j-th data line Dj to the first node N1 in response to the first scan signal GW[i].

The third transistor T3 may be connected between the first node N1 and a third node N3. A gate electrode of the third transistor T3 may be connected to a (4i)-th scan line S4i (or third scan line). The third transistor T3 may be turned on when the fourth scan signal GC[i] is supplied to the (4i)-th scan line S4i. When the third transistor T3 is turned on, the first transistor T1 may have a diode-connected structure.

The fourth transistor T4 may be connected between the first node N1 and a second power line PL2. A gate electrode of the fourth transistor T4 may be connected to a (2i)-th scan line S2i (or second scan line). A first initialization power voltage Vint1 may be provided to the second power line PL2. For example, the first initialization power voltage Vint1 may be about −3.5 V. The fourth transistor T4 may be turned on by a second scan signal GI[i] supplied to the (2i)-th scan line S2i. When the fourth transistor T4 is turned on, the first initialization power voltage Vint1 may be supplied to the first node N1 (that is, to the gate electrode of the first transistor T1).

The fifth transistor T5 may be connected between the first power line PL1 and the second node N2. A gate electrode of the fifth transistor T5 may be connected to an i-th light-emitting control line Ei. The sixth transistor T6 may be connected between the third node N3 and the light-emitting element LED (or the fourth node N4). A gate electrode of the sixth transistor T6 may be connected to the i-th light-emitting control line Ei. When a light-emitting control signal EM[i] (for example, a high-level light-emitting control signal EM[i]) is supplied to the i-th light-emitting control line Ei, the fifth transistor T5 and the sixth transistor T6 may be turned off, and in other cases, they may be turned on.

The seventh transistor T7 (or switching transistor) may be connected between the first electrode (that is, the fourth node N4) of the light-emitting element LED and the third power line PL3. A gate electrode of the seventh transistor T7 may be connected to a (3i)-th scan line S3i. A second initialization power voltage Vint2 may be provided to the third power line PL3. For example, the second initialization power voltage Vint2 may be about −3.5 V. In some embodiments, the second initialization power voltage Vint2 may be different from the first initialization power voltage Vint1. The seventh transistor T7 may be turned on by a third scan signal GB[i] supplied to the (3i)-th scan line S3i to supply the second initialization power voltage Vint2 to the first electrode of the light-emitting element LED.

The storage capacitor Cst may be connected or formed between the first power line PL1 and the first node N1.

The photo sensor PHS may include a sensor circuit SC and a light-receiving element LRD. The sensor circuit SC may include ninth, tenth, and eleventh transistors T9, T10, and T11) and a first capacitor C1.

The tenth and eleventh transistors T10 and T11 may be connected in series between the third power line PL3 and the k-th readout line RXk (wherein k is a natural number).

The tenth transistor T10 (or the first sensor transistor) may be connected between the third power line PL3 and the eleventh transistor T11. A gate electrode of the tenth transistor T10 may be connected to a fifth node N5 (or a sensor node). The tenth transistor T10 may control a current flowing from the third power line PL3 to the k-th readout line RXk through the eleventh transistor T11 in response to the voltage of the fifth node N5.

The eleventh transistor T11 (or the second sensor transistor) may be connected between the tenth transistor T10 and the k-th readout line RXk. A gate electrode of the eleventh transistor T11 may be connected to the (1i)-th scan line S1i. That is, the gate electrode of the eleventh transistor T11 and the gate electrode of the second transistor T2 may share the (1i)-th scan line S1i.

The eleventh transistor T11 may include a first sub-transistor T11-1 and a second sub-transistor T11-2 connected in series between the tenth transistor T10 and the k-th readout line RXk. That is, the eleventh transistor T11 may be implemented as a dual-gate transistor. In this case, current leakage through the eleventh transistor T11 and the resulting sensing error of the sensor circuit SC may be reduced, and the stability of the photo sensor PHS may be improved.

The first capacitor C1 may be formed or electrically connected between a constant voltage wire and a sixth node N6 (or a first middle node) to which the first and second sub-transistors T11-1 and T11-2 are connected. The constant voltage wire is a wiring to which a constant voltage (or a DC voltage) is applied, and for example, the constant voltage wire may be the third power line PL3, but is not limited thereto.

For reference, when the sensor circuit SC does not include the first capacitor C1, the sixth node N6 may be in a floating state, the voltage of the sixth node N6 may be undesirably changed by coupling between the sixth node N6 and adjacent signal lines, and current leakage through the eleventh transistor T11 may occur. The first capacitor C1 may reduce or prevent undesirable change of a voltage of the sixth node N6.

The ninth transistor T9 (or third sensor transistor) may be connected between the fourth power line PL4 (or reference power line) and the fifth node N5. A gate electrode of the ninth transistor T9 may be connected to the reset control line RSTL. The reset voltage VRST is provided to the fourth power line PL4, and for example, the reset voltage VRST may be about −4.5 V.

At least one light-receiving element LRD may be connected between the fifth node N5 and the electrode EP to which the second power voltage VSS is provided.

The light-receiving element LRD may generate a charge (or current) based on incident light. That is, the light-receiving element LRD may perform a function of photoelectric conversion. For example, the light-receiving element LRD may be implemented as a photodiode.

When the ninth transistor T9 is turned on by the reset signal RST supplied to the reset control line RSTL, the reset voltage VRST may be provided to the fifth node N5. For example, the voltage of the fifth node N5 may be reset by the reset voltage VRST. After the reset voltage VRST is applied to the fifth node N5, the light-receiving element LRD may perform a function of photoelectric conversion.

The voltage of the fifth node N5 may be changed by the operation of the light-receiving element LRD. The voltage (or charge or current generated by the light-receiving element LRD) of the fifth node N5 may vary according to the intensity of light incident on the light-receiving element LRD, and according to the time at which the light is incident (or the time at which the light-receiving element LRD is exposed to light).

When the tenth transistor T10 is turned on by the second scan signal GI[i] supplied to the (2i)-th scan line S2i, a detection value (current and/or voltage) generated based on the voltage of the fifth node N5 may flow to the k-th readout line RXk.

Each of the pixel circuit PXC and the sensor circuit SC may include a P-type transistor and an N-type transistor. The third transistor T3, the fourth transistor T4, and the ninth transistor T9 may be formed as oxide semiconductor transistors including an oxide semiconductor (or a second type semiconductor). For example, the third transistor T3, the fourth transistor T4, and the ninth transistor T9 may be an N-type oxide semiconductor transistor, and may include an oxide semiconductor layer as an active layer.

The oxide semiconductor transistor may be processed at a low temperature, and has lower charge mobility than that of the polysilicon semiconductor transistor. That is, the oxide semiconductor transistor has an excellent off-current characteristic. Accordingly, leakage current in the third transistor T3, the fourth transistor T4, and the ninth transistor T9 may be reduced or minimized.

The remaining transistors (for example, the first, second, fifth, sixth, seventh, tenth, and eleventh transistors T1, T2, T5, T6, T7, T10, and T11) may be formed as a polysilicon transistor including a silicon semiconductor (or a first type semiconductor), and may include a polysilicon semiconductor layer as an active layer. For example, the active layer may be formed through a low temperature polysilicon process (for example, a low temperature polysilicon (LTPS) process). For example, the polysilicon transistor may be a P-type polysilicon transistor. Because the polysilicon semiconductor transistor has an advantage of a fast response speed, it may be applied to a switching element using fast switching.

As described above, the pixel circuit PXC and the sensor circuit SC may share a scan line (for example, the (1i)-th scan line S1i), and the pixel circuit PXC and the sensor circuit SC may be scanned at the same time. In this case, the number of wires located on the display panel 100 (see FIG. 1) may be relatively reduced, and the resolution deterioration due to wires (for example, relatively many wires) may be alleviated. In addition, the driver (for example, the scan driver 211) for driving the pixel PX and the photo sensor PHS may be integrated, and the space for the driver may be reduced.

In addition, the eleventh transistor T11 may be implemented as a dual-gate transistor, and the first capacitor C1 may be connected between the middle node (that is, the sixth node N6) of the eleventh transistor T11 and the constant voltage wire (for example, the third power line PL3). Accordingly, the current leaking to the k-th readout line RXk may be reduced or minimized, and the sensing sensitivity of the photo sensor PHS including the sensor circuit SC may be improved.

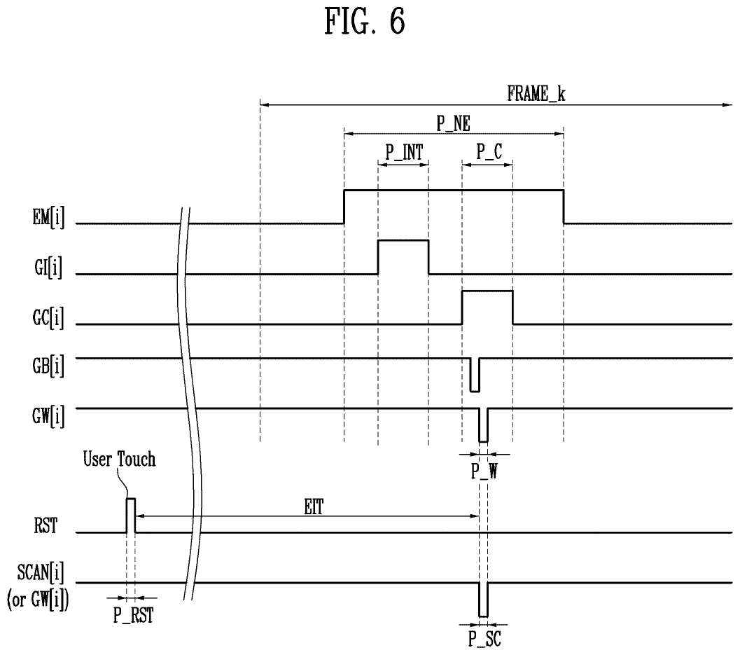

FIG. 6 illustrates a waveform diagram of one or more embodiments of an operation of the pixel and the photo sensor of FIG. 5.

Referring to FIG. 1, FIG. 2, FIG. 5, and FIG. 6, the light lighting control signal EM[i] may be provided to the i-th light lighting control line Ei, the second scan signal GI[i] may be provided to the (2i)-th scan line S2i, the fourth scan signal GC[i] may be provided to the (4i)-th scan line S4i, the third scan signal GB[i] may be provided to the (3i)-th scan line S3i, and the first scan signal GW[i] may be provided to the (1i)-th scan line S1i. The reset signal RST may be provided to the reset control line RSTL. The sensing scan signal SCAN[i] (or the i-th sensing scan signal) may refer to a signal provided to the gate electrode of the eleventh transistor T11. Because the gate electrode of the eleventh transistor T11 is connected to the (1i)-th scan line S1i, the sensing scan signal SCAN[i] may be the first scan signal GW[i].

The k-th frame period FRAME_k may include a non-light-emitting period P_NE. The non-light-emitting period P_NE (or the k-th frame period FRAME_k) may include an initialization period P_INT, a compensation period P_C, and a writing period P_W. The writing period P_W may be included in the compensation period P_C.

In the non-light-emitting period P_NE, the light-emitting control signal EM[i] may have a high-level. In this case, the fifth transistor T5 and the sixth transistor T6 may be turned off in response to the high-level light-emitting control signal EM[i], and the pixel PX may not emit light.

In the initialization period P_INT, the second scan signal GI[i] may have a high-level. In this case, the fourth transistor T4 may be turned on in response to the high-level second scan signal GI[i], and the first initialization power voltage Vint1 of the second power line PL2 may be provided to the first node N1 (or to the gate electrode of the first transistor T1).

Thereafter, the fourth scan signal GC[i] may have a high-level during the compensation period P_C. The third transistor T3 may be turned on in response to the high-level fourth scan signal GC[i], and the first transistor T1 may be diode-connected.

In the writing period P_W, the first scan signal GW[i] may have a low-level. In this case, the second transistor T2 may be turned on in response to the low-level first scan signal GW[i], and the data signal may be provided from the j-th data line Dj to the second node N2. In addition, because the third transistor T3 is turned on in response to the high-level fourth scan signal GC[i], the data signal may be transmitted from the second node N2 to the first node N1 through the first transistor T1 and the third transistor T3. Because the first transistor T1 remains diode-connected by the turned-on third transistor T3, the voltage of the first node N1 may have a voltage in which the threshold voltage of the first transistor T1 is compensated for the data signal.

Before the writing period P_W, the third scan signal GB[i] may have a low-level. In this case, the seventh transistor T7 may be turned on in response to the low-level third scan signal GB[i], and the second initialization power voltage Vint2 may be supplied to the first electrode of the light-emitting element LED. The third scan signal (GB[i]) may be the first scan signal (for example, GW[i−1]) provided in the previous row, but is not limited thereto.

Thereafter, the non-light-emitting period P_NE may end, and the light-emitting control signal EM[i] may have a low-level. In this case, the fifth transistor T5 and the sixth transistor T6 may be turned on in response to the low-level light-emitting control signal EM[i]. Further, a current movement path may be formed from the first power line PL1 to the electrode EP through the fifth transistor T5, the first transistor T1, the sixth transistor T6, and the light-emitting element LED. Also, according to the operation of the first transistor T1, the driving current corresponding to the voltage (for example, data signal) of the first node N1 may flow through the light-emitting element LED. Additionally, the light-emitting element LED may emit light with luminance corresponding to the driving current.

Meanwhile, the reset signal RST may have a high-level in a reset period P_RST before the k-th frame period FRAME_k. When a user's touch input or fingerprint detection request occurs, the reset circuit 221 (see FIG. 2) may provide the high-level reset signal RST to the reset control line RSTL. In response to the high-level reset signal RST, the ninth transistor T9 may be turned on, and the reset voltage VRST may be applied to the fifth node N5. The voltage of the fifth node N5 may be reset by the reset voltage VRST.

Thereafter, the ninth transistor T9 may be turned off in response to the low-level reset signal RST. When light is incident on the light-receiving element LRD during the exposure time EIT, the voltage of the fifth node N5 may be changed by the photoelectric conversion function of the light-receiving element LRD.

In the sensing scan period P_SC of the k-th frame period FRAME_k, the sensing scan signal SCAN[i], that is, the first scan signal GW[i] may have a low-level. The sensing scan period P_SC may be the same as the initialization period P_INT. The eleventh transistor T11 may be turned on in response to the first scan signal GW[i], and a current (or a detection value) may flow from the third power line PL3 to the k-th readout line RXk in response to the voltage of the fifth node N5.

For example, when a user's touch input occurs on the display panel 100, a current corresponding to the light reflected by the user (for example, a user's finger), that is, a detection value may be outputted in the k-th frame period FRAME_k. For example, a user's fingerprint may be detected based on the detection value.

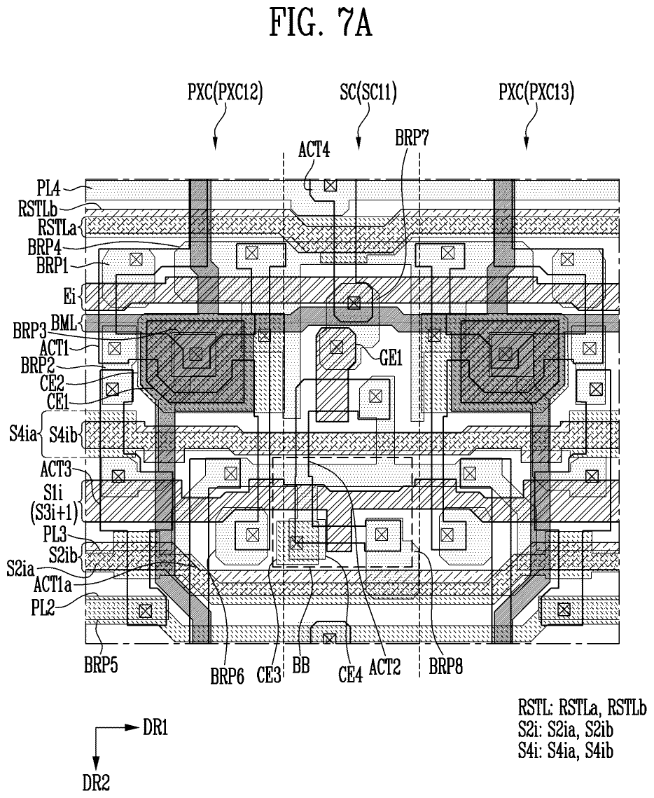

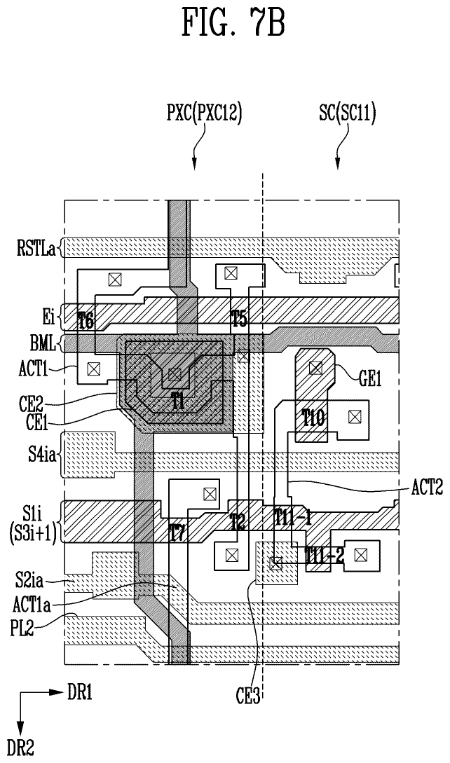

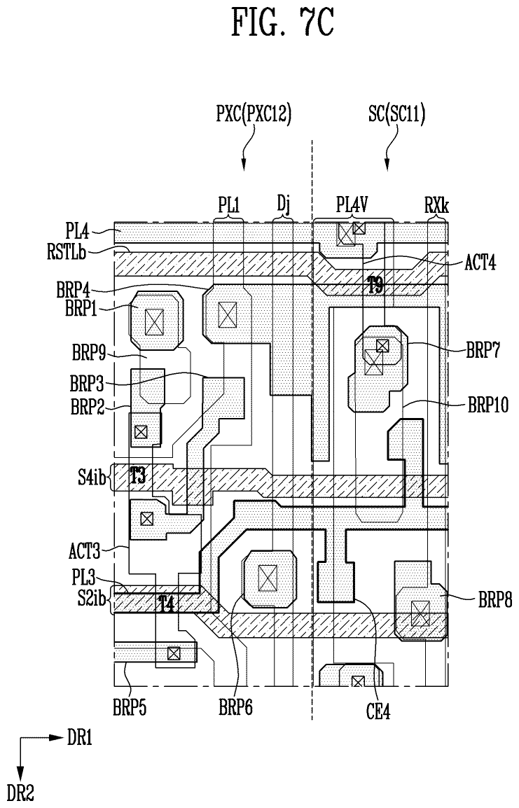

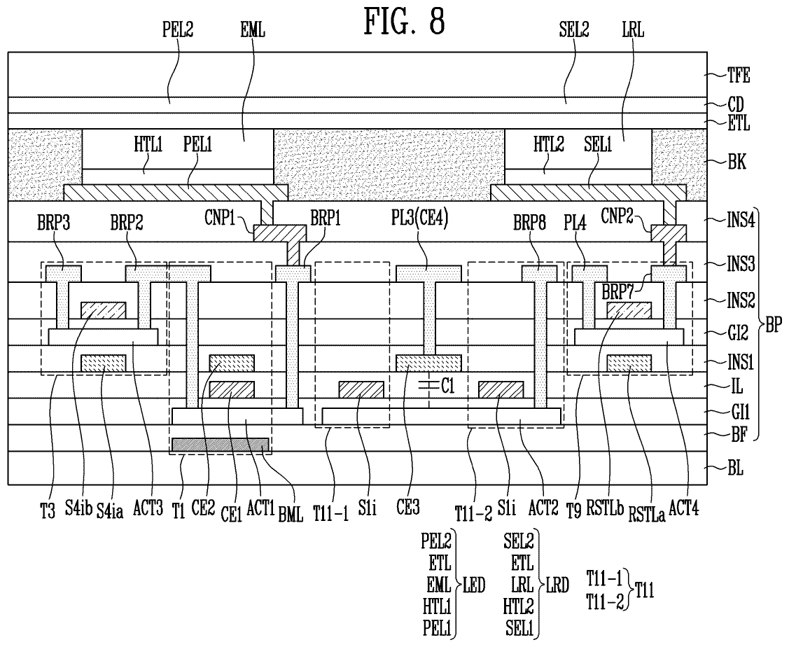

FIG. 7A, FIG. 7B, and FIG. 7C illustrate top plan views of one or more embodiments of the display area of FIG. 4. FIG. 7A, FIG. 7B, and FIG. 7C illustrate the pixel circuit PXC and the sensor circuit SC of FIG. 5. Based on the first insulating layer INS1 of FIG. 8, some lower components of the pixel circuit PXC (and sensor circuit SC) are illustrated in FIG. 7B, and some upper components of the pixel circuit PXC (and sensor circuit SC) are illustrated in FIG. 7C. FIG. 8 illustrates a cross-sectional view of one or more embodiments of the display area of FIG. 4.

In FIG. 7A to FIG. 8, the sub-pixel is simplified by showing each electrode as an electrode of a single film, and showing each insulating layer as an insulating layer of a single film, but the present disclosure is not limited thereto.

In describing embodiments of the present disclosure, “formed and/or provided in the same layer” may mean formed in the same process, and “formed and/or provided in different layers” may mean formed in different processes.

In FIG. 7A, FIG. 7B, and FIG. 7C, a horizontal direction in a plan view is denoted as a first direction DR1, and a vertical direction in a plan view is denoted as a second direction DR2.

Referring to FIG. 4, FIG. 5, FIG. 7A, FIG. 7B, FIG. 7C, and FIG. 8, the sensor circuit SC may correspond to the first sensor circuit SC11 of FIG. 4, and based on the sensor circuit SC, the pixel circuit PXC on the left and the pixel circuit PXC on the right may correspond to the twelfth pixel circuit PXC12 and the thirteenth pixel circuit PXC13, respectively. Based on the sensor circuit SC, the pixel circuit PXC on the left and the pixel circuit PXC on the right may be substantially symmetrical, and may be substantially the same or similar. Accordingly, the pixel circuit PXC (that is, the twelfth pixel circuit PXC12) on the left side will be described on the basis, and redundant descriptions will not be repeated. For convenience, only the pixel circuit PXC (that is, the twelfth pixel circuit PXC12) and the sensor circuit SC on the left side are illustrated in FIG. 7B and FIG. 7C.

Hereinafter, components will be described according to the order in which they are stacked on the base layer BL with reference to FIG. 8.

The base layer BL (or substrate) may be made of an insulating material, such as glass or a resin. In addition, the base layer BL may be made of a flexible material to be bendable or foldable, and may have a single-layered structure or a multi-layered structure.

A backplane structure BP including the pixel circuit PXC and the sensor circuit SC may be provided on the base layer BL. The backplane structure BP may include a semiconductor layer, a plurality of conductive layers, and a plurality of insulating layers.

A lower electrode BML may be located on the base layer BL. The lower electrode BML may overlap the first transistor T1 (or the first capacitor electrode CE1 and the second capacitor electrode CE2) in a plan view. The lower electrode BML may shield the first transistor T1 (or the first capacitor electrode CE1 and the second capacitor electrode CE2) from the lower portion. A constant voltage may be applied to the lower electrode BML. For example, the first power voltage VDD may be applied to the lower electrode BML, but is not limited thereto. The lower electrode BML may extend in the first direction DR1 and the second direction DR2 with respect to the first transistor T1. The lower electrode BML may have a mesh structure throughout the display area.

The lower electrode BML may include a conductive material. For example, the conductive material may include copper (Cu), molybdenum (Mo), tungsten (W), aluminum neodymium (AlNd), titanium (Ti), aluminum (Al), silver (Ag), and/or an alloy thereof.

A buffer layer BF may be provided on the base layer BL to cover the lower electrode BML. The buffer layer BF may be an insulating film including an inorganic material. For example, the inorganic material may include at least one of metal oxides, such as a silicon nitride (SiNₓ), a silicon oxide (SiOₓ), a silicon oxynitride (SiOₓN_{y}), and/or an aluminum oxide (AlOₓ). The buffer layer BF may be provided as a single film, but may be provided as a multifilm of at least double or more films. The buffer layer BF may reduce or prevent diffusion of impurities into the transistor.

A first semiconductor pattern ACT1 (or a first active pattern or a first semiconductor layer) of the pixel circuit PXC, and a second semiconductor pattern ACT2 (or a second active pattern or a second semiconductor layer) of the sensor circuit SC, may be located on the buffer layer BF. The first semiconductor pattern ACT1 and the second semiconductor pattern ACT2 may be formed of a polysilicon semiconductor.

The first semiconductor pattern ACT1, which overlaps the first capacitor electrode CE1, may form the channel area of the first transistor T1. The first semiconductor pattern ACT1 may extend from both ends of the channel area of the first transistor T1 in a direction opposite to the second direction DR2. The first semiconductor pattern ACT1 overlapping the i-th light-emitting control line Ei may configure the channel area of the fifth transistor T5 and the channel area of the sixth transistor T6. The first semiconductor pattern ACT1 may further extend from the channel area of the sixth transistor T6 in a direction opposite to the second direction DR2, and the first semiconductor pattern ACT1 overlapping the (1i)-th scan line S1i (or the (1a)-th semiconductor pattern ACT1a overlapping the (3i+1)-th scan line S3i+1 of FIG. 7B) may configure the channel area of the seventh transistor T7. The first semiconductor pattern ACT1 may extend in the second direction DR2 from the right end portion of the channel area of the first transistor T1, and the first semiconductor pattern ACT1 overlapping the (1i)-th scan line S1i may configure the channel area of the second transistor T2.

For example, the channel area, which is a semiconductor pattern that is not doped with impurities, may be an intrinsic semiconductor. The remaining area (for example, the remaining area of the first semiconductor pattern ACT1) of the semiconductor panel excluding the channel area may be a semiconductor pattern doped with impurities.

The second semiconductor pattern ACT2 may be spaced apart from the first semiconductor pattern ACT1 in the first direction DR1. The second semiconductor pattern ACT2, which overlaps the first gate electrode GE1, may configure the channel area of the tenth transistor T10. The second semiconductor pattern ACT2, which overlaps the (1i)-th scan line S1i, may configure the channel area of the eleventh transistor T11 or the first and second sub-transistors T11-1 and T11-2.

A first gate-insulating layer GI1 may be located on the first semiconductor pattern ACT1 and the second semiconductor pattern ACT2. The first gate-insulating layer GI1 may be an insulating film made of an inorganic material.

A first capacitor electrode CE1, a first gate electrode GE1, an i-th light-emitting control line Ei, and a (1i)-th scan line S1i (and the (3i+1)-th scan line S3i+1 of FIG. 7B) may be located on the first gate-insulating layer GI1. The first capacitor electrode CE1, the first gate electrode GE1, the i-th light-emitting control line Ei, and the (1i)-th scan line S1i may include a conductive material.

The first capacitor electrode CE1 overlapping the first semiconductor pattern ACT1 may configure the gate electrode of the first transistor T1.

The first gate electrode GE1 overlapping the first semiconductor pattern ACT1 may configure the gate electrode of the tenth transistor T10.

In a plan view, the i-th light-emitting control line Ei and the (1i)-th scan line S1i may be spaced apart from each other with the first capacitor electrode CE1 interposed therebetween, and each of the i-th light-emitting control line Ei and the (1i)-th scan line S1i may extend in the first direction DR1.

The i-th light-emitting control line Ei overlapping the first semiconductor pattern ACT1 may configure the gate electrode of the fifth transistor T5 and the gate electrode of the sixth transistor T6.

The (1i)-th scan line S1i overlapping the first semiconductor pattern ACT1 may configure the gate electrode of the second transistor T2. In addition, the (1i)-th scan line S1i (or the (3i+1)-th scan line S3i+1 of FIG. 7B) overlapping the first semiconductor pattern ACT1 may configure the gate electrode of the seventh transistor T7.

An interlayer insulating layer IL may be located on the first capacitor electrode CE1, the first gate electrode GE1, the i-th light-emitting control line Ei, the (1i)-th scan line S1i (and the (3i+1)-th scan line S3i+1 of FIG. 7B). The interlayer insulating layer IL may be an insulating layer made of an inorganic material.

A second capacitor electrode CE2, a third capacitor electrode CE3, a first sub-reset control line RSTLa, a (2ia)-th scan line S2ia (or first sub-scan line), and a second power line PL2 (or second horizontal power line) may be located on the interlayer insulating layer IL. The second capacitor electrode CE2, the third capacitor electrode CE3, the first sub-reset control line RSTLa, the (2ia)-th scan line S2ia, the (4ia)-th scan line S4ia, and the second power line PL2 may include a conductive material. The first sub-reset control line RSTLa may form the reset control line RSTL together with the second sub-reset control line RSTLb. Similarly, the (2ia)-th scan line S2ia may configure the (2i)-th scan line S2i together with the (2ib)-th scan line S2ib (or the third sub scan line), and the (4ia)-th scan line S4ia may configure the (4i)-th scan line S4i together with the (4ib)-th scan line S4ib (or the fourth sub scan line).

The second capacitor electrode CE2 may overlap the first capacitor electrode CE1, and may form the storage capacitor Cst. Most of the first capacitor electrode CE1 may overlap the first capacitor electrode CE1. The second capacitor electrode CE2 may include/define an opening that exposes the first capacitor electrode CE1.

The third capacitor electrode CE3 may overlap the second semiconductor pattern ACT2. For example, the third capacitor electrode CE3 may overlap a portion (for example, an area doped with impurities) of the second semiconductor pattern ACT2 between the channel area of the first sub-transistor T11-1 and the channel area of the second sub-transistor T11-2. The third capacitor electrode CE3 and the portion of the second semiconductor pattern ACT2 may form the first capacitor C1.

In a plan view, the first sub-reset control line RSTLa, the (2ia)-th scan line S2ia, and the second power line PL2 may be spaced apart from each other in the second direction DR2, and each of the first sub-reset control line RSTLa, the (2ia)-th scan line S2ia, the (4ia)-th scan line S4ia, and the second power line PL2 may extend in the first direction DR1.

The first insulating layer INS1 may be located on the second capacitor electrode CE2, the third capacitor electrode CE3, the first sub-reset control line RSTLa, the (2ia)-th scan line S2ia, the (4ia)-th scan line S4ia, and the second power line PL2. The first insulating layer INS1 may be an insulating film made of an inorganic material.

A third semiconductor pattern ACT3 (or a third active pattern and a third semiconductor layer) of the pixel circuit PXC and a fourth semiconductor pattern ACT4 (or a fourth active pattern and a fourth semiconductor layer) of the sensor circuit SC may be located on the first insulating layer INS1. The third semiconductor pattern ACT3 and the fourth semiconductor pattern ACT4 may be formed of an oxide semiconductor. Each of the third semiconductor pattern ACT3 and the fourth semiconductor pattern ACT4 may substantially extend in the second direction DR2.

The third semiconductor pattern ACT3 overlapping the (4ia)-th scan line S4ia(and the (4ib)-th scan line S4ib) may configure the channel area of the third transistor T3. The third semiconductor pattern ACT3 overlapping the (2ia)-th scan line S2ia (and the (2ib)-th scan line S2ib) may configure the channel area of the fourth transistor T4.

The fourth semiconductor pattern ACT4 overlapping the first sub-reset control line RSTLa may configure the channel area of the ninth transistor T9.

A second gate-insulating layer GI2 may be located on the third semiconductor pattern ACT3 and the fourth semiconductor pattern ACT4. The second gate-insulating layer GI2 may be an insulating layer made of an inorganic material.

The second sub-reset control line RSTLb, the (2ib)-th scan line S2ib (or the third sub-scan line), and the (4ib)-th scan line S4ib (or the fourth sub-scan line) may be located on the second gate-insulating layer GI2. The (2ib)-th scan line S2ib and the (4ib)-th scan line S4ib may include a conductive material.

In a plan view, the second sub-reset control line RSTLb, the (2ib)-th scan line S2ib, and the (4ib)-th scan line S4ib may be spaced apart from each other in the second direction DR2, and each of the second sub-reset control line RSTLb, the (2ib)-th scan line S2ib, and the (4ib)-th scan line S4ib may extend in the first direction DR1.

The second sub-reset control line RSTLb may overlap the first sub-reset control line RSTLa. In addition, the second sub-reset control line RSTLb overlapping the fourth semiconductor pattern ACT4 may configure the gate electrode (or first gate electrode) of the ninth transistor T9. Meanwhile, the first sub-reset control line RSTLa overlapping the fourth semiconductor pattern ACT4 may configure the lower gate electrode (or second gate electrode) of the ninth transistor T9.

The (2ib)-th scan line S2ib may overlap the (2ia)-th scan line S2ia. In addition, the (2ib)-th scan line S2ib overlapping the third semiconductor pattern ACT3 may configure the gate electrode (or first gate electrode) of the fourth transistor T4. Meanwhile, the (2ia)-th scan line S2ia overlapping the third semiconductor pattern ACT3 may configure the lower gate electrode (or second gate electrode) of the fourth transistor T4.

The (4ib)-th scan line S4ib may overlap the (4ia)-th scan line S4ia. In addition, the (4ib)-th scan line S4ib overlapping the third semiconductor pattern ACT3 may configure the gate electrode (or first gate electrode) of the third transistor T3. Meanwhile, the (4ia)-th scan line S4ia overlapping the third semiconductor pattern ACT3 may configure the lower gate electrode (or second gate electrode) of the third transistor T3.

A second insulating layer INS2 may be located on the second sub-reset control line RSTLb, the (2ib)-th scan line S2ib, and the (4ib)-th scan line S4ib. The second insulating layer INS2 may be an insulating layer made of an inorganic material.

The third power line PL3, the fourth power line PL4, and the bridge patterns BRP1 to BRP8 may be located on the second insulating layer INS2. The third power line PL3, the fourth power line PL4, and the bridge patterns BRP1 to BRP8 may include a conductive material.

The third power line PL3 may substantially extend in the first direction DR1. The third power line PL3 may extend in the first direction DR1 between the tenth transistor T10 and the eleventh transistor T11. The third power line PL3 may protrude in a direction opposite to the second direction DR2 in an area adjacent to the tenth transistor T10, and may overlap the upper end portion of the second semiconductor pattern ACT2. The third power line PL3 may contact the upper end portion of the second semiconductor pattern ACT2 through a contact hole. In addition, the third power line PL3 protrudes in the second direction DR2 in an area adjacent to the eleventh transistor T11, and the protruding portion CE4 of the third power line PL3 may overlap the third capacitor electrode CE3. The third power line PL3 may contact the third capacitor electrode CE3 through a contact hole penetrating at least one insulating layer (for example, a contact hole penetrating the first insulating layer INS1 to the second insulating layer INS2).

The first bridge pattern BRP1 may overlap the first semiconductor pattern ACT1, and may be connected to the first semiconductor pattern ACT1 through a contact hole. The first bridge pattern BRP1 may be electrically connected to the light-emitting element LED (see FIG. 8), and the first bridge pattern BRP1 may configure the fourth node N4 of FIG. 5.

The second bridge pattern BRP2 may overlap the first semiconductor pattern ACT1, and may be connected to the first semiconductor pattern ACT1 (or one electrode of the first transistor T1) through a contact hole. In addition, the second bridge pattern BRP2 may overlap the third semiconductor pattern ACT3, and may be connected to the third semiconductor pattern ACT3 (or one electrode of the third transistor T3) through a contact hole. The second bridge pattern BRP2 may electrically connect the first transistor T1 and the third transistor T3. The second bridge pattern BRP2 may configure the third node N3 in FIG. 5.

The third bridge pattern BRP3 may overlap the first capacitor electrode CE1, and may be connected to the first capacitor electrode CE1 through a contact hole (and an opening of the second capacitor electrode CE2). In addition, the third bridge pattern BRP3 may overlap the third semiconductor pattern ACT3, and may be connected to the third semiconductor pattern ACT3 (or the other electrode of the third transistor T3) through a contact hole. The third bridge pattern BRP3 may electrically connect the first capacitor electrode CE1 (or the storage capacitor Cst) and the third transistor T3. The third bridge pattern BRP3 may configure the first node N1 in FIG. 5.

The fourth bridge pattern BRP4 may overlap the first power line PL1 (or first vertical power line PL1).

The fifth bridge pattern BRP5 may overlap the lower end portions of the second power line PL2 and the third semiconductor pattern ACT3, and may be connected to the lower end portions of the second power line PL2 and the third semiconductor pattern ACT3, respectively.

The sixth bridge pattern BRP6 may overlap a portion of the first semiconductor pattern ACT1 adjacent to the second transistor T2 and the j-th data line Dj, and may be connected to a portion of the first semiconductor pattern ACT1 adjacent to the second transistor T2 and the j-th data line Dj, respectively.

The seventh bridge pattern BRP7 may overlap the first gate electrode GE1, and may be connected to the first gate electrode GE1 (or the gate electrode of the tenth transistor T10) through a contact hole. In addition, the seventh bridge pattern BRP7 may overlap the fourth semiconductor pattern ACT4, and may be connected to the fourth semiconductor pattern ACT4 (or one electrode of the ninth transistor T9) through a contact hole. The seventh bridge pattern BRP7 may electrically connect the gate electrode of the tenth transistor T10 and the ninth transistor T9. The seventh bridge pattern BRP7 may configure the fifth node N5 in FIG. 5.

The eighth bridge pattern BRP8 may overlap the second semiconductor pattern ACT2 (or one electrode of the eleventh transistor T11) and the k-th readout line RXk, and may be connected to the second semiconductor pattern ACT2 and the k-th readout line RXk, respectively.

A third insulating layer INS3 may be located on the third power line PL3, the fourth power line PL4, and the bridge patterns BRP1 to BRP8. The third insulating layer INS3 may be an insulating layer made of an inorganic material or an organic material. For example, the organic material may include an acrylic resin, an epoxy resin, a phenol resin, a polyamide resin, a polyimide resin, and the like.

The first power line PL1 (or first vertical power line), the j-th data line Dj, a fourth vertical power line PL4V, the k-th readout line RXk, the ninth bridge pattern BRP9, and the tenth bridge pattern BRP10 may be located on the third insulating layer INS3. The first power line PL1, the j-th data line Dj, the fourth vertical power line PL4V, the k-th readout line RXk, the ninth bridge pattern BRP9, and the tenth bridge pattern BRP10 may include a conductive material.

The first power line PL1, the j-th data line Dj, the fourth vertical power line PL4V, and the k-th readout line RXk may be spaced apart from each other along the first direction DR1, and each of them may extend in the second direction DR2. The first power line PL1 may be connected to the fourth bridge pattern BRP4 through a contact hole. The j-th data line Dj may be connected to the sixth bridge pattern BRP6 through a contact hole. The k-th readout line RXk may be connected to the eighth bridge pattern BRP8 through a contact hole.

The ninth bridge pattern BRP9 may overlap the first bridge pattern BRP1, and may be connected to the first bridge pattern BRP1 through a contact hole.

The tenth bridge pattern BRP10 may overlap the seventh bridge pattern BRP7, and may be connected to the seventh bridge pattern BRP7 through a contact hole.

A fourth insulating layer INS4 may be located on the first power line PL1 (or the first vertical power line), the j-th data line Dj, the fourth vertical power line PL4V, the k-th readout line RXk, the ninth bridge pattern BRP9, and the tenth bridge pattern BRP10. The fourth insulating layer INS4 may be an insulating layer made of an organic material and/or an inorganic material. The fourth insulating layer INS4 may serve as a planarization layer.

A pixel layer including a first pixel electrode PEL1, a first sensor electrode SEL1, and a bank layer BK may be provided on the fourth insulating layer INS4.

The pixel layer may include a light-emitting element LED connected to the pixel circuit PXC and a light-receiving element LRD connected to the sensor circuit SC.

The light-emitting element LED may include a first pixel electrode PEL1, a first hole transport layer HTL1, a light-emitting layer EML, an electron transport layer ETL, and a second pixel electrode PEL2. The light-receiving element LRD may include a first sensor electrode SEL1, a second hole transport layer HTL2, a light-receiving layer LRL, an electron transport layer ETL, and a second sensor electrode SEL2.

The first pixel electrode PEL1 and the first sensor electrode SEL1 may be made of a metal layer, such as silver (Ag), magnesium (Mg), aluminum (Al), platinum (Pt), palladium (Pd), gold (Au), nickel (Ni), neodymium (Nd), iridium (Ir), chromium (Cr), and/or an alloy thereof, and/or an indium tin oxide (IZO), an indium zinc oxide (IZO), a zinc oxide (ITO), and/or a zinc oxide (ITO). The first pixel electrode PEL1 may be connected to a first connection pattern CNP1 through a contact hole. The first sensor electrode SEL1 may be connected to a second connection pattern CNP2 through a contact hole.

The first pixel electrode PEL1 and the first sensor electrode SEL1 may be concurrently or substantially simultaneously formed through patterning using a mask.

The bank layer BK (or pixel-defining film) for partitioning the light-emitting area and the light-receiving area may be provided on the fourth insulating layer INS4 on which the first pixel electrode PEL1 and the first sensor electrode SEL1 are formed. The bank layer BK may be an insulating layer made of an organic material.

In some embodiments, the bank layer BK may include a light-absorbing material, or may serve to absorb light introduced from the outside by a light absorption agent being applied thereon. For example, the bank layer BK may include a carbon-based black pigment. However, it is not limited thereto, and the bank layer BK may include an opaque metallic material, such as chromium (Cr), molybdenum (Mo), an alloy (MoTi) of molybdenum and titanium, tungsten (W), vanadium (V), niobium (Nb), tantalum (Ta), manganese (Mn), cobalt (Co), or nickel (Ni), which has a high light absorption rate.

The bank layer BK may include/define openings corresponding to the light-emitting area and the light-receiving area.

The first hole transport layer HTL1 may be provided on the upper surface of the first pixel electrode PEL1 that is exposed by the bank layer BK, and the second hole transport layer HTL2 may be provided on the upper surface of the exposed first sensor electrode SEL1. Through the first hole transport layer HTL1, holes may move to the light-emitting layer EML, and through the second hole transport layer HTL2, holes may move to the light-receiving layer LRL.

Depending on the materials of the light-emitting layer EML and the light-receiving layer LRL, the first hole transport layer HTL1 and the second hole transport layer HTL2 may be substantially the same, or may be different.

The light-emitting layer EML may be provided on the first hole transport layer HTL1. The light-emitting layer EML may be configured as an organic light-emitting layer. Depending on the organic material included in the light-emitting layer EML, the light-emitting layer EML may emit light, such as red light, green light, or blue light.

An electron-blocking layer may be provided on the second hole transport layer HTL2 in the light-receiving area. The electron-blocking layer may reduce or prevent the likelihood of charges from the light-receiving layer LRL moving to the hole transport layer HTL. The electron-blocking layer may be omitted, in one or more embodiments.

The light-receiving layer LRL may be located on the second hole transport layer HTL2. The light-receiving layer LRL may detect the intensity of light by emitting electrons in response to light of a corresponding wavelength band.

The light-receiving layer LRL may include a low molecular weight organic material. For example, the light-receiving layer LRL is made of a phthalocyanine compound containing at least one metal selected from a group consisting of copper (Cu), iron (Fe), nickel (Ni), cobalt (Co), manganese (Mn), aluminum (Mn), aluminum (Al), palladium (Pd), tin (Sn), indium (In), lead (Pb), titanium (Ti), rubidium (Rb), vanadium (V), gallium (Ga), terbium (Tb), cerium (Ce), lanthanum (La), and/or zinc (Zn).

In addition, the low molecular weight organic material included in the light-receiving layer LRL may be configured of two layers (a bi-layer) including a layer including a phthalocyanine compound including one or more of copper (Cu), iron (Fe), nickel (Ni), cobalt (Co), manganese (Mn), aluminum (Mn), aluminum (Al), palladium (Pd), tin (Sn), indium (In), lead (Pb), titanium (Ti), rubidium (Rb), vanadium (V), gallium (Ga), terbium (Tb), cerium (Ce), lanthanum (La), and/or zinc (Zn) and a layer including C60, or may be configured of one mixing layer in which a phthalocyanine compound and C60 are mixed.

However, this is an example, and the light-receiving layer LRL may include a polymer organic layer.

The light-receiving layer LRL may determine a photo detection band of the photo sensor by controlling selection of a metal component included in the phthalocyanine compound. For example, in a case of a phthalocyanine compound including copper, it absorbs a visible light wavelength of a band ranging from about 600 nm to about 800 nm, and in a case of a phthalocyanine compound including tin (Sn), it absorbs a near-infrared wavelength of a band ranging from about 800 nm to about 1000 nm. Accordingly, by controlling the selection of the metal included in the phthalocyanine compound, it is possible to implement a photo sensor that may detect the wavelength of the band desired by the user. For example, the light-receiving layer LRL may be formed to selectively absorb a wavelength of a red light band, a wavelength of a green light band, or a wavelength of a blue light band.

An area of the light-receiving area may be smaller than that of the light-emitting area.

The second pixel electrode PEL2 and the second sensor electrode SEL2 may be provided on the electron transport layer ETL. The second pixel electrode PEL2 and the second sensor electrode SEL2 may be a common electrode CD integrally formed on the display area AA. The second power voltage VSS may be supplied to the second pixel electrode PEL2 and second sensor electrode SEL2.

The common electrode CD may be formed of a metal layer made of silver (Ag), magnesium (Mg), aluminum (Al), platinum (Pt), palladium (Pd), gold (Au), nickel (Ni), neodymium (Nd), iridium (Ir), or chromium (Cr) and/or a transparent conductive layer made of ITO, IZO, ZnO, or ITZO. The common electrode CD may be formed of a multilayer of two layers or more including a thin metal layer, for example, a triple layer of ITO/Ag/ITO.

An encapsulation layer TFE may be provided on the common electrode CD including the second pixel electrode PEL2 and the second sensor electrode SEL2. The encapsulation layer TFE may be provided as a single layer or as a multi-layer. The encapsulation layer TFE may have a stacked structure in which an inorganic material, an organic material, and an inorganic material are sequentially deposited. An uppermost layer of the encapsulation layer TFE may be formed of an inorganic material.

As described above, between the channel area of the first sub-transistor T11-1 and the channel area of the second sub-transistor T11-2, the third capacitor electrode CE3 may be located on a portion (for example, an area doped with impurities) of the second semiconductor pattern ACT2, and the third capacitor electrode CE3 may be connected to the third power line PL3. The third capacitor electrode CE3 and the portion of the second semiconductor pattern ACT2 may form the first capacitor C1. Accordingly, the current leaking through the eleventh transistor T11 may be reduced or minimized, and the accuracy of sensing using the photo sensor including the sensor circuit SC may be improved.

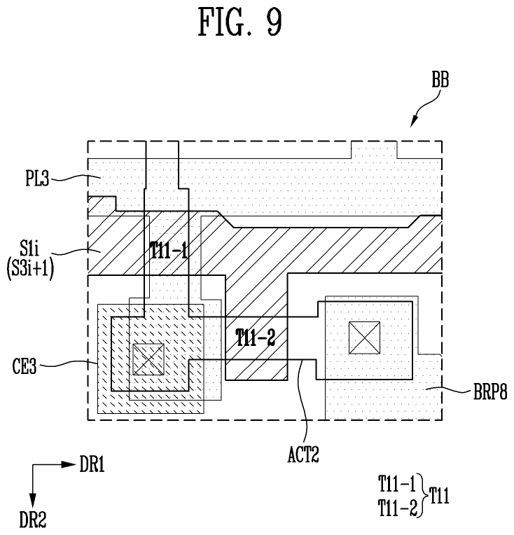

FIG. 9 illustrates a top plan view of one or more embodiments of area BB of FIG. 7A.

Referring to FIG. 4, FIG. 5, FIG. 7A to FIG. 7C, FIG. 8, and FIG. 9, the shape of the second semiconductor pattern ACT2 may be variously modified.

For example, the second semiconductor pattern ACT2 may include a portion protruding or extending in the opposite direction of the first direction DR1 and/or the second direction DR2 between the channel area of the first sub-transistor T11-1 and the channel area of the second sub-transistor T11-2. The mentioned portion of the second semiconductor pattern ACT2 may increase the overlap area with the third capacitor electrode CE3, and may increase the capacity of the first capacitor C1. That is, the capacity of the first capacitor C1 may be adjusted by increasing or reducing the mentioned portion of the second semiconductor pattern ACT2.

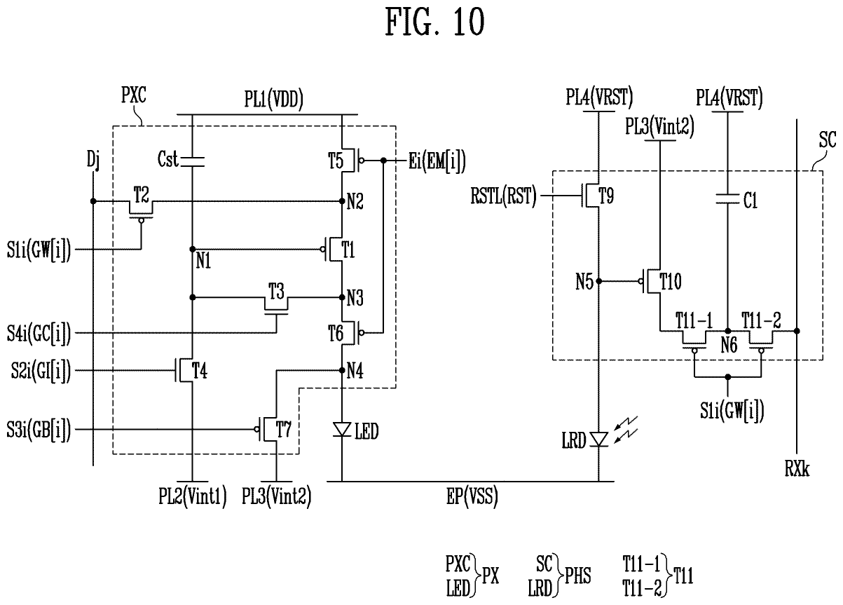

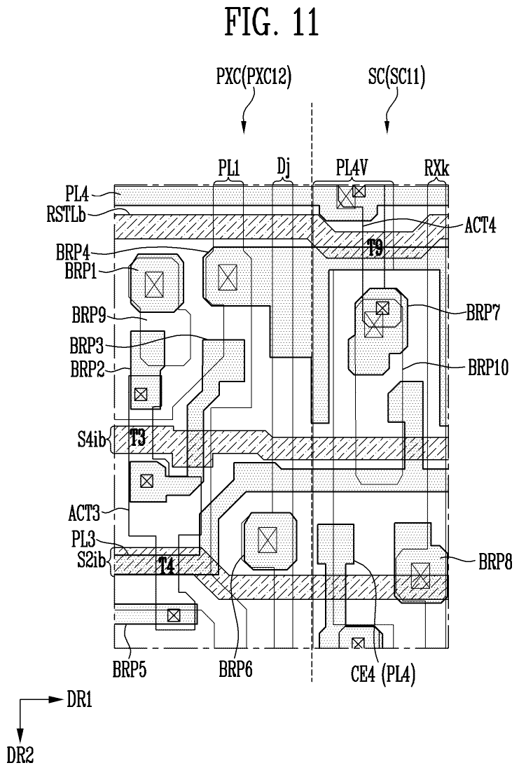

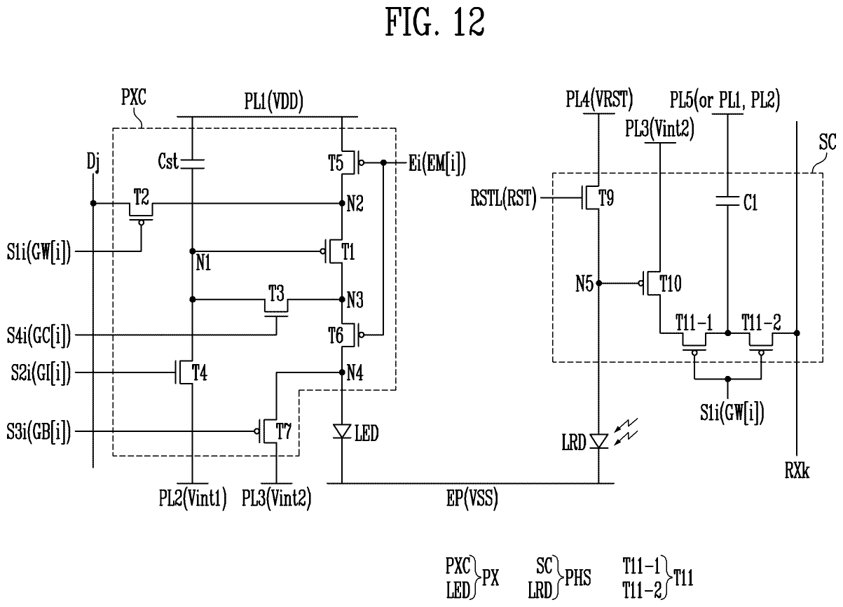

FIG. 10 illustrates a circuit diagram of one or more embodiments of a pixel and a photo sensor included in the display area of FIG. 4. FIG. 11 illustrates a top plan view of one or more embodiments of a display area of FIG. 4. In FIG. 11, similar to FIG. 7C, some components of the upper portion of the pixel circuit PXC (and the sensor circuit SC) are illustrated based on the first insulating layer INS1 of FIG. 8. FIG. 12 illustrates a circuit diagram of one or more other embodiments of a pixel and a photo sensor included in the display area of FIG. 4.

Referring to FIG. 4, FIG. 5, FIG. 7A to FIG. 7C, FIG. 10, and FIG. 11, except for the third power line PL3 and the protruding portion CE4, the sensor circuit SC (and the pixel circuit PXC) of FIG. 10 and FIG. 11 may be substantially the same as or similar to the sensor circuit SC (and the pixel circuit PXC) of FIG. 5 and FIG. 7A to FIG. 7C. Therefore, redundant descriptions will not be repeated.

The first capacitor C1 may be electrically connected between the sixth node N6 (or a first middle node), to which the first and second sub-transistors T11-1 and T11-2 are connected, and the fourth power line PL4. The same voltage as that of the fourth power line PL4 to which the ninth transistor T9 is connected may be applied to the constant voltage wire to which the first capacitor C1 is connected.

In this case, as illustrated in FIG. 11, the third power line PL3 may not include a portion protruding in the second direction DR2 (that is, a portion protruding toward the eleventh transistor T11 of FIG. 7B), but the fourth power line PL4 may include the portion CE4 protruding in a direction opposite to the second direction DR2. The protruding portion CE4 of the fourth power line PL4 may overlap the third capacitor electrode CE3 of FIG. 7B, and may contact the third capacitor electrode CE3 through a contact hole penetrating at least one insulating layer.

Meanwhile, the first capacitor C1 is described as being electrically connected to the fourth power line PL4 with reference to FIG. 10 and FIG. 11, but is not limited thereto. As illustrated in FIG. 12, the first capacitor C1 may be electrically connected to the fifth power line PL5. In some embodiments, the fifth power line PL5 may be electrically connected to the first power line PL1 or to the second power line PL2, or the same voltage as the first power line PL1 or the second power line PL2 may be applied to the fifth power line PL5. That is, the first capacitor C1 is connected to a constant voltage wire, and the constant voltage wire is not limited to a specific wire.

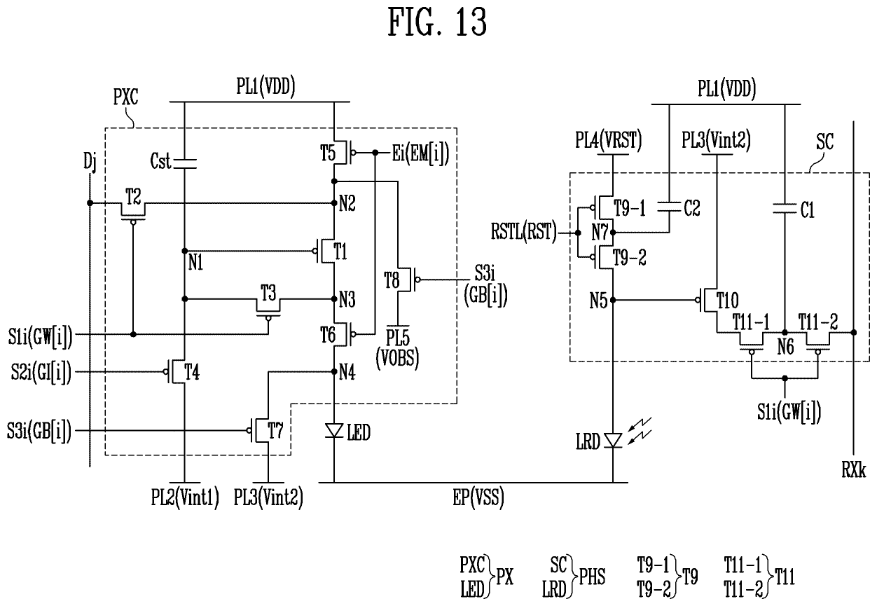

FIG. 13 illustrates a circuit diagram of one or more other embodiments of a pixel and a photo sensor included in the display area of FIG. 4.

Referring to FIG. 4, FIG. 5, and FIG. 13, the sensor circuit SC (and the pixel circuit PXC) of FIG. 13 may be substantially the same as or similar to the sensor circuit SC (and the pixel circuit PXC) of FIG. 5, except for the second, third, fourth, eighth, and ninth transistors T2, T3, T4, T8, and T9 and the second capacitor C2. Therefore, redundant descriptions will not be repeated.

The transistors T1 to T11 may include a silicon semiconductor. For example, the transistors T1 to T11 may be formed of a polysilicon transistor, and may include a polysilicon semiconductor layer as an active layer. For example, the polysilicon transistor may be a P-type transistor.

The gate electrode of the third transistor T3 may be connected to the (1i)-th scan line S1i (or first scan line). The third transistor T3, which is a polysilicon transistor, may be turned on when the first scan signal GW[i] (that is, the low-level first scan signal) is supplied to the (1i)-th scan line S1i. In some embodiments, the third transistor T3 may be implemented as a dual-gate transistor.

The fourth transistor T4 may be connected between the first node N1 and the second power line PL2. The gate electrode of the fourth transistor T4 may be connected to the (2i)-th scan line S2i (or second scan line). The fourth transistor T4, which is a polysilicon transistor, may be turned on by the second scan signal GI[i] (that is, the low-level second scan signal) supplied to the (2i)-th scan line S2i. In some embodiments, the fourth transistor T4 may be implemented as a dual-gate transistor.

The eighth transistor T8 may be connected between the second node N2 and the fifth power line PL5. The gate electrode of the eighth transistor T8 may be connected to a (3i)-th scan line S3i. A bias voltage VOBS may be provided to the fifth power line PL5. The eighth transistor T8 may be turned on by the third scan signal GB[i] supplied to the (3i)-th scan line S3i, and may transmit the bias voltage VOBS to the first electrode of the first transistor T1. The bias voltage VOBS may be set to a voltage level suitable for compensating for hysteresis characteristics of the first transistor T1. In some embodiments, the eighth transistor T8 may be omitted.

The ninth transistor T9 (or third sensor transistor) may be connected between the fourth power line PL4 (or reference power line) and the fifth node N5. The gate electrode of the ninth transistor T9 may be connected to the reset control line RSTL. The reset voltage VRST is provided to the fourth power line PL4, and for example, the reset voltage VRST may be about −4.5 V.

The ninth transistor T9 (or the third sensor transistor) may include a third sub-transistor T9-1 and a fourth sub-transistor T9-2 connected in series between the fourth power line PL4 (or the reference power line) and the fifth node N5. That is, the ninth transistor T9 may be implemented as a dual-gate transistor. In this case, current leakage through the ninth transistor T9 may be reduced.

The first capacitor C1 may be formed or electrically connected between the constant voltage line and the sixth node N6 (or a first middle node) to which the first and second sub-transistors T11-1 and T11-2 are connected. For example, the constant voltage wire to which the first capacitor C1 is connected may be the first power line PL1, but is not limited thereto.

The second capacitor C2 may be formed or electrically connected between the constant-voltage wire and the seventh node N7 (or the second intermediate node) to which the third and fourth sub-transistors T9-1 and T9-2 are connected. The constant voltage wire to which the second capacitor C2 is connected may be the first power line PL1, but is not limited thereto. The second capacitor C2 may reduce or prevent undesirable change of the voltage of the seventh node N7, and may reduce or prevent current leakage through the ninth transistor T9.

As described above, the ninth transistor T9 may be implemented as a dual-gate transistor, and the second capacitor C2 may be connected between the middle node (that is, the seventh node N7) of the ninth transistor T9 and the constant voltage line (for example, the first power line PL1). Accordingly, the leakage current between the fifth node N5 and the fourth power line PL4 may be reduced or minimized, and the sensing sensitivity of the photo sensor PHS including the sensor circuit SC may be improved.

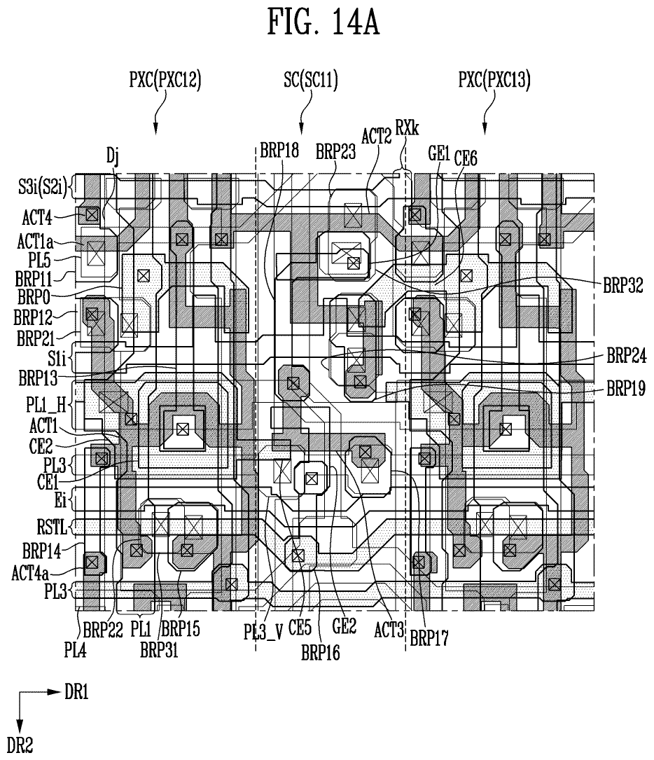

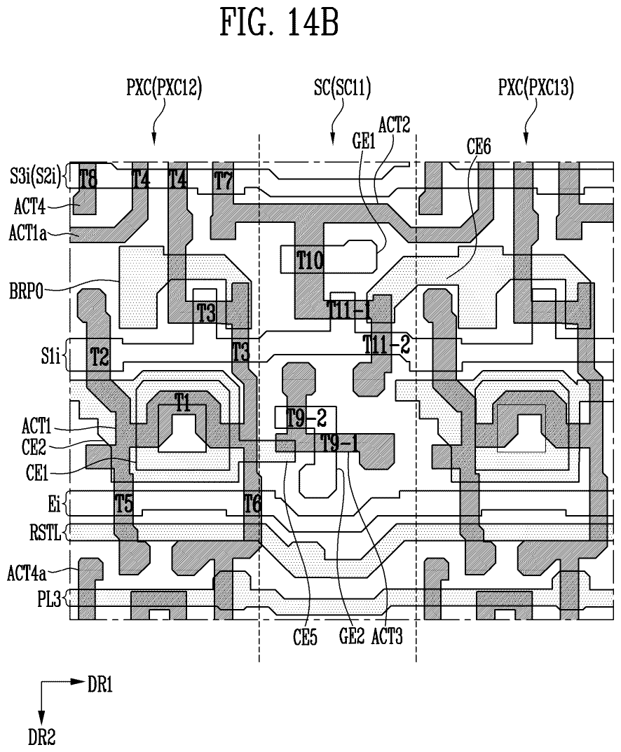

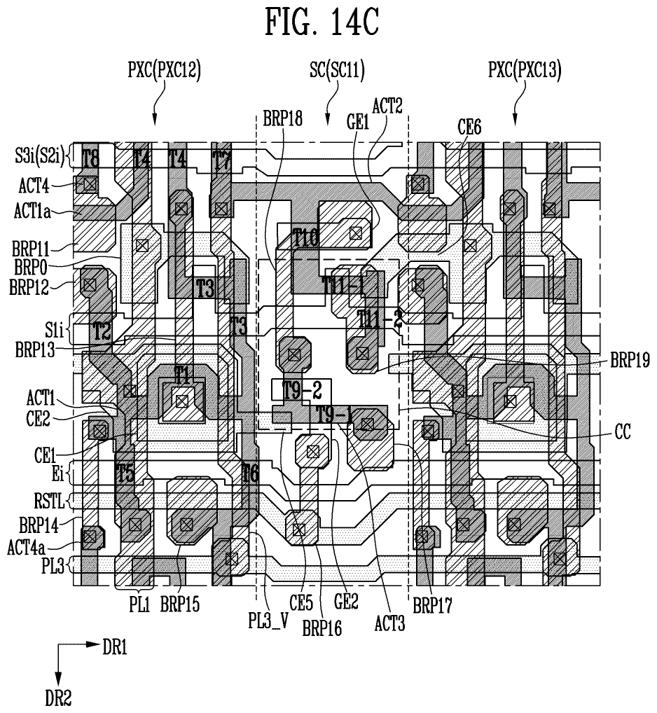

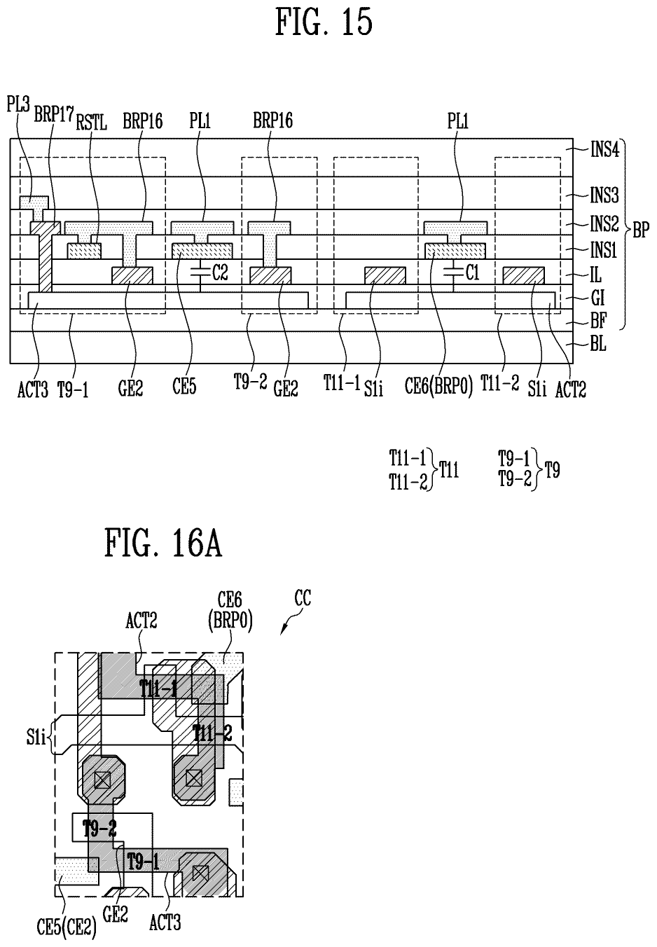

FIG. 14A, FIG. 14B, and FIG. 14C illustrate top plan views of one or more embodiments of the display area of FIG. 4. FIG. 14A, FIG. 14B, and FIG. 14C illustrate the pixel circuit PXC and the sensor circuit SC of FIG. 15. Based on the first insulating layer INS1 of FIG. 15, some lower components of the pixel circuit PXC (and sensor circuit SC) are illustrated in FIG. 14B, and some upper components of the pixel circuit PXC (and sensor circuit SC) are further illustrated in FIG. 14C. FIG. 15 illustrates a cross-sectional view of one or more embodiments of the display area of FIG. 4. For convenience, FIG. 15 is illustrated focusing on the backplane structure BP, and the remaining components (for example, the pixel layer) of FIG. 8 may also be applied to FIG. 15.

Referring to FIG. 4, FIG. 5, FIG. 14A, FIG. 14B, FIG. 14C, and FIG. 15, the sensor circuit SC may correspond to the first sensor circuit SC11 of FIG. 4, and based on the sensor circuit SC, the pixel circuit PXC on the left and the pixel circuit PXC on the right may correspond to the twelfth pixel circuit PXC12 and the thirteenth pixel circuit PXC13, respectively. Based on the sensor circuit SC, the pixel circuit PXC on the left and the pixel circuit PXC on the right may be substantially symmetrical and may be substantially the same or similar. Accordingly, the pixel circuit PXC (that is, the twelfth pixel circuit PXC12) on the left side will be described on the basis, and redundant descriptions will not be repeated.

Hereinafter, components will be described according to the order in which they are stacked on the base layer BL with reference to FIG. 15. Meanwhile, because the general characteristics of the components have been described with reference to FIG. 7A, FIG. 7B, FIG. 7C, and FIG. 8, differences from the embodiments of FIG. 7A, FIG. 7B, FIG. 7C, and FIG. 8 will be mainly described.

The backplane structure BP including the pixel circuit PXC and the sensor circuit SC may be provided on the base layer BL. The backplane structure BP may include a semiconductor layer, a plurality of conductive layers, and a plurality of insulating layers.

The first semiconductor pattern ACT1 (or the first active pattern or the first semiconductor layer) and the fourth semiconductor pattern ACT4 (or the fourth active pattern or the fourth semiconductor layer) of the pixel circuit PXC, and the second semiconductor pattern ACT2 (or the second active pattern or the second semiconductor layer) and the third semiconductor pattern ACT3 (or the third active pattern or the third semiconductor layer) of the sensor circuit SC may be located on the buffer layer BF. The first semiconductor pattern ACT1, the second semiconductor pattern ACT2, the third semiconductor pattern ACT3, and the fourth semiconductor pattern ACT4 may be formed of a polysilicon semiconductor.

The first semiconductor pattern ACT1, which overlaps the first capacitor electrode CE1, may form the channel area of the first transistor T1. The first semiconductor pattern ACT1 may extend from both ends of the channel area of the first transistor T1 in the second direction DR2, and the first semiconductor pattern ACT1 overlapping the i-th light-emitting control line Ei may configure the channel area of the fifth transistor T5 and the channel area of the sixth transistor T6. The first semiconductor pattern ACT1 may further extend in the second direction DR2 from the channel area of the sixth transistor T6, and the first semiconductor pattern ACT1 (or a portion of the first semiconductor pattern ACT1 connected to the second semiconductor pattern ACT2) overlapping the (3i)-th scan line S3i may configure the channel area of the seventh transistor T7. In addition, the first semiconductor pattern ACT1 may extend in a direction opposite to the second direction DR2 from the left end portion of the channel area of the first transistor T1, and the first semiconductor pattern ACT1 overlapping the (1i)-th scan line S1i may configure the channel area of the second transistor T2. The first semiconductor pattern ACT1 may extend in a direction opposite to the second direction DR2 from the right end portion of the channel area of the first transistor T1, and the first semiconductor pattern ACT1 overlapping the (1i)-th scan line S1i may configure the channel area of the third transistor T3. In addition, the first semiconductor pattern ACT1 may further extend in a direction opposite to the second direction DR2 from the third transistor T3, and the first semiconductor pattern ACT1 overlapping the (2i)-th scan line S2i may configure the channel area of the fourth transistor T4. In order to implement the fourth transistor T4 as a dual-gate transistor, the first semiconductor pattern ACT1 may further extend in the second direction DR2, and may further include a portion (that is, the (1a)-th semiconductor pattern ACT1a) having a curved shape.

The second semiconductor pattern ACT2 may be spaced apart from the first semiconductor pattern ACT1 in the first direction DR1. The second semiconductor pattern ACT2, which overlaps the first gate electrode GE1, may configure the channel area of the tenth transistor T10. The second semiconductor pattern ACT2, which overlaps the (1i)-th scan line S1i, may configure the channel area of the eleventh transistor T11 or the first and second sub-transistors T11-1 and T11-2.

The third semiconductor pattern ACT3 may be spaced apart from the second semiconductor pattern ACT2 in the second direction DR2. The third semiconductor pattern ACT3 overlapping the second gate electrode GE2 may configure the channel area of the ninth transistor T9 or the third and fourth sub-transistors T9-1 and T9-2.

The fourth semiconductor pattern ACT4 may be located to overlap the (3i)-th scan line S3i, and may configure the channel area of the eighth transistor T8. For connection with other components, for example, for connection with the first transistor T1 through the fourteenth bridge pattern BRP14, the fourth semiconductor pattern ACT4 may include a portion ACT4a extending in a direction opposite to the second direction DR2.

The gate-insulating layer GI may be located on the first semiconductor pattern ACT1, the second semiconductor pattern ACT2, and the third semiconductor pattern ACT3. The gate-insulating layer GI may be an insulating layer made of an inorganic material.

The first capacitor electrode CE1, the first gate electrode GE1, the second gate electrode GE2, the i-th light-emitting control line Ei, the (1i)-th scan line S1i, and the (3i)-th scan line S3i may be located on the gate-insulating layer GI.

The first capacitor electrode CE1 overlapping the first semiconductor pattern ACT1 may configure the gate electrode of the first transistor T1.

The first gate electrode GE1 overlapping the second semiconductor pattern ACT2 may configure the gate electrode of the tenth transistor T10.

The second gate electrode GE2 overlapping the third semiconductor pattern ACT3 may configure the gate electrode of the ninth transistor T9.

In a plan view, the i-th light-emitting control line Ei and the (1i)-th scan line S1i may be spaced apart from each other with the first capacitor electrode CE1 interposed therebetween, and each of the i-th light-emitting control line Ei and the (1i)-th scan line S1i may extend in the first direction DR1. The (2i)-th scan line S2i may be spaced apart from the i-th light-emitting control line Ei and the (1i)-th scan line S1i, and may extend in the first direction DR1.

The i-th light-emitting control line Ei overlapping the first semiconductor pattern ACT1 may configure the gate electrode of the fifth transistor T5 and the gate electrode of the sixth transistor T6.

The (1i)-th scan line S1i overlapping the first semiconductor pattern ACT1 may configure the gate electrode of the second transistor T2 and the gate electrode of the third transistor T3. In addition, the (1i)-th scan line S1i overlapping the second semiconductor pattern ACT2 may configure the gate electrode of the eleventh transistor T11. For the third transistor T3 and the fourth transistor T4 respectively implemented as a dual-gate transistor, the (1i)-th scan line S1i may include portions protruding in a direction opposite to the second direction DR2.

The (3i)-th scan line S3i overlapping the first semiconductor pattern ACT1 may configure the gate electrode of the seventh transistor T7. The (3i)-th scan line S3i overlapping the fourth semiconductor pattern ACT4 may configure the gate electrode of the eighth transistor T8. The (2i)-th scan line S2i overlapping the first semiconductor pattern ACT1 may configure the gate electrode of the fourth transistor T4.

The interlayer insulating layer IL may be located on the first capacitor electrode CE1, the first gate electrode GE1, the second gate electrode GE2, the i-th light-emitting control line Ei, the (1i)-th scan line S1i, and the (3i)-th scan line S3i. The interlayer insulating layer IL may be an insulating layer made of an inorganic material.

A zeroth bridge pattern BRP0, a second capacitor electrode CE2, a reset control line RSTL, and a third power line PL3 may be located on the interlayer insulating layer IL.

The zeroth bridge pattern BRP0 may overlap the middle node of the third transistor T3. The zeroth bridge pattern BRP0 of the thirteenth pixel circuit PXC13 may include a portion (that is, the sixth capacitor electrode CE6) protruding toward the second semiconductor pattern ACT2, and may overlap the second semiconductor pattern ACT2 between the first sub-transistor T11-1 and the second sub-transistor T11-2. The mentioned portion (that is, the sixth capacitor electrode CE6) of the zeroth bridge pattern BRP0 and the second semiconductor pattern ACT2 overlapping the same may configure the first capacitor C1. In other words, the sixth capacitor electrode CE6 configuring the first capacitor C1 may protrude toward the third transistor T3 to overlap the middle node of the third transistor T3.

The second capacitor electrode CE2 may overlap the first capacitor electrode CE1, and may form the storage capacitor Cst. The second capacitor electrode CE2 may further include a portion protruding toward the third semiconductor pattern ACT3 (that is, the fifth capacitor electrode CE5 having a size that is smaller than that of the second capacitor electrode CE2). The mentioned portion (that is, the fifth capacitor electrode CE5) of the second capacitor electrode CE2 may overlap the third semiconductor pattern ACT3 between the third sub-transistor T9-1 and the fourth sub-transistor T9-2, and may configure the second capacitor C2. That is, the second capacitor electrode CE2 of the storage capacitor Cst and the fifth capacitor electrode CE5 of the second capacitor C2 may be integrally formed.

The reset control line RSTL and the third power line PL3 may be spaced apart from each other in the second direction DR2, and each of the reset control line RSTL and the third power line PL3 may extend in the first direction DR1.

The first insulating layer INS1 may be located on the zeroth bridge pattern BRP0, the second capacitor electrode CE2, the reset control line RSTL, and the third power line PL3. The first insulating layer INS1 may be an insulating film made of an inorganic material.

The first power line PL1, the third vertical power line PL3_V, and the bridge patterns BRP11 to BRP19 may be located on the first insulating layer INS1.

The first power line PL1 may substantially extend in the second direction DR2, and may be connected to the second capacitor electrode CE2 and the zeroth bridge pattern BRP0 through a contact hole.

The third vertical power line PL3_V may substantially extend in the second direction DR2, and may be connected to the first semiconductor pattern ACT1 and the third power line PL3 configuring one electrode of the seventh transistor T7 through contact holes.

The eleventh bridge pattern BRP11 may overlap the fourth semiconductor pattern ACT4, and may be connected to the fourth semiconductor pattern ACT4 through a contact hole. The eleventh bridge pattern BRP11 may connect the fourth semiconductor pattern ACT4 configuring the eighth transistor T8 and the fifth power line PL5.

The twelfth bridge pattern BRP12 may overlap the first semiconductor pattern ACT1 configuring one electrode of the second transistor T2, and may be connected to the first semiconductor pattern ACT1 through a contact hole. The twelfth bridge pattern BRP12 may connect the first semiconductor pattern ACT1 configuring one electrode of the second transistor T2 and the j-th data line DLj.

The thirteenth bridge pattern BRP13 may be connected to the first capacitor electrode CE1 through the opening and the contact hole of the second capacitor electrode CE2, and may be connected to the first semiconductor pattern ACT1 through the contact hole between the third transistor T3 and the fourth transistor T4. The thirteenth bridge pattern BRP13 may connect the node between the third and fourth transistors T3 and T4 to the first capacitor electrode CE1.

The fourteenth bridge pattern BRP14 may be connected to the first semiconductor pattern ACT1 configuring one electrode of the first transistor T1 through a contact hole, and may be connected to the fourth semiconductor pattern ACT4 (or a portion ACT4a) through a contact hole. The fourteenth bridge pattern BRP14 may connect the eighth transistor T8 to one electrode of the first transistor T1.

The fifteenth bridge pattern BRP15 may be connected to the first semiconductor pattern ACT1 configuring one electrode of the sixth transistor T6 through a contact hole. The fifteenth bridge pattern BRP15 may connect the sixth transistor T6 to the pixel layer.

The sixteenth bridge pattern BRP16 may be connected to the second gate electrode GE2 through a contact hole, and may be be connected to the reset control line RSTL through a contact hole. The sixteenth bridge pattern BRP16 may connect the second gate electrode GE2 of the ninth transistor T9 and the reset control line RSTL.

The seventeenth bridge pattern BRP17 may be connected to the third semiconductor pattern ACT3 through a contact hole. The seventeenth bridge pattern BRP17 may connect the third semiconductor pattern ACT3 configuring the ninth transistor T9 to the third power line PL3.

The eighteenth bridge pattern BRP18 may be connected to the first gate electrode GE1 through a contact hole, and may be connected to the third semiconductor pattern ACT3 through a contact hole. The eighteenth bridge pattern BRP18 may connect the third semiconductor pattern ACT3 configuring the ninth transistor T9 and the first gate electrode GE1 of the tenth transistor T10.

The nineteenth bridge pattern BRP19 may be connected to the second semiconductor pattern ACT2 configuring one electrode of the eleventh transistor T11 through a contact hole. The nineteenth bridge pattern BRP19 may connect the eleventh transistor T11 and the k-th readout line RXk.

The second insulating layer INS2 may be located on the first power line PL1, the third vertical power line PL3_V, and the bridge patterns BRP11 to BRP19. The second insulating layer INS2 may be an insulating layer made of an inorganic material.

The first horizontal power line PL1_H, the third power line PL3, the fourth power line PL4, the fifth power line PL5, and the bridge patterns BRP21 to BRP24 may be located on the second insulating layer INS2.

The first horizontal power line PL1_H, the third power line PL3, the fourth power line PL4, and the fifth power line PL5 may be spaced apart from each other in the second direction DR2, and each of the first horizontal power line PL1_H, the third power line PL3, the fourth power line PL4, and the fifth power line PL5 may substantially extend in the first direction DR1.

The first horizontal power line PL1_H may be connected to the first power line PL1 through a contact hole.

The third power line PL3 may be connected to the third vertical power line PL3_V through a contact hole.

The fourth power line PL4 may be connected to the third semiconductor pattern ACT3 configuring the first electrode of the ninth transistor T9 through a contact hole.

The fifth power line PL5 may have a partially curved shape to bypass the twenty-third bridge pattern BRP23, and may be connected to the eleventh bridge pattern BRP11 through a contact hole.

The twenty-first bridge pattern BRP21 may be connected to the twelfth bridge pattern BRP12 through a contact hole. The twenty-first bridge pattern BRP21 may connect the twelfth bridge pattern BRP12 and the j-th data line Dj.

The twenty-second bridge pattern BRP22 may be connected to the fifteenth bridge pattern BRP15 through a contact hole. The twenty-second bridge pattern BRP22 may be connected to the fifteenth bridge pattern BRP15 and the thirty-first bridge pattern BRP31 (or the light-emitting element of the pixel layer).

The twenty-third bridge pattern BRP23 may be connected to the eighteenth bridge pattern BRP18 through a contact hole. The twenty-third bridge pattern BRP23 may connect the eighteenth bridge pattern BRP18 and the thirty-second bridge pattern BRP32 (or the light-receiving element of the pixel layer).

The twenty-fourth bridge pattern BRP24 may be connected to the nineteenth bridge pattern BRP19 through a contact hole. The twenty-fourth bridge pattern BRP24 may be connected to the nineteenth bridge pattern BRP19 and the k-th readout line RXk.

The third insulating layer INS3 may be located on the first horizontal power line PL1_H, the third power line PL3, the fourth power line PL4, the fifth power line PL5, and the bridge patterns BRP21 to BRP24. The third insulating layer INS3 may be an insulating layer made of an inorganic material or an organic material.

The j-th data line Dj, the k-th readout line RXk, the thirty-first bridge pattern BRP31, and the thirty-second bridge pattern BRP32 may be located on the third insulating layer INS3.

The j-th data line Dj and the k-th readout line RXk may be spaced apart from each other in the first direction DR1, and each of the j-th data line Dj and the k-th readout line RXk may substantially extend in the second direction DR2.

The fourth insulating layer INS4 may be located on the j-th data line Dj, the k-th readout line RXk, the thirty-first bridge pattern BRP31, and the thirty-second bridge pattern BRP32. The fourth insulating layer INS4 may be an insulating layer made of an organic material and/or an inorganic material. The fourth insulating layer INS4 may serve as a planarization layer.

The pixel layer described with reference to FIG. 8 may be provided on the fourth insulating layer INS4.

As described above, between the channel area of the first sub-transistor T11-1 and the channel area of the second sub-transistor T11-2, the sixth capacitor electrode CE6 may be located on a portion (for example, an area doped with impurities) of the second semiconductor pattern ACT2, and the sixth capacitor electrode CE6 may be connected to the third power line PL3. The sixth capacitor electrode CE6 and the portion of the second semiconductor pattern ACT2 may form the first capacitor C1. Accordingly, the current leaking through the eleventh transistor T11 may be reduced or minimized.

In addition, between the channel area of the third sub-transistor T9-1 and the channel area of the fourth sub-transistor T9-2, the fifth capacitor electrode CE5 may be located on a portion (for example, an area doped with impurities) of the third semiconductor pattern ACT3, and the fifth capacitor electrode CE5 may be connected to the first power line PL1 through the second capacitor electrode CE2. The fifth capacitor electrode CE5 and the mentioned portion of the third semiconductor pattern ACT3 may form the second capacitor C2. Accordingly, the current leaking through the ninth transistor T9 may be reduced or minimized, and the accuracy of sensing using the photo sensor including the sensor circuit SC may be improved.

Meanwhile, in FIG. 13 to FIG. 15, the sensor circuit SC is illustrated as including the ninth transistor T9 and the eleventh transistor T11, each of which is a dual-gate transistor, and the first capacitor C1 and the second capacitor C2, but is not limited thereto. For example, the sensor circuit SC may include only one of the ninth transistor T9 and the eleventh transistor T11 as a dual-gate transistor, and may include only the first capacitor C1 or the second capacitor C2 connected to the dual-gate transistor.

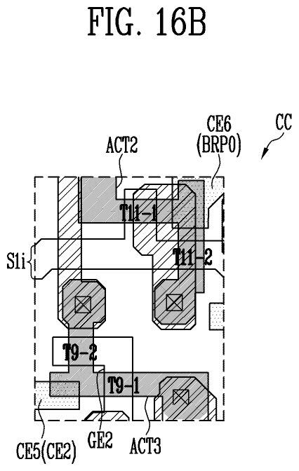

FIG. 16A and FIG. 16B illustrate plan views of one or more embodiments of area CC of FIG. 14C.

Referring to FIG. 4, FIG. 5, FIG. 15A to FIG. 15C, FIG. 16A, and FIG. 16B, the shape of the second semiconductor pattern ACT2 and the shape of the third semiconductor pattern ACT3 may be variously modified.

For example, compared to the one or more embodiments corresponding to FIG. 14B, as illustrated in FIG. 16A, the second semiconductor pattern ACT2 may not include a portion protruding or extending in the opposite direction of the second direction DR2 between the channel area of the first sub-transistor T11-1 and the channel area of the second sub-transistor T11-2. As another example, compared to the one or more embodiments corresponding to FIG. 14B, as illustrated in FIG. 16B, the second semiconductor pattern ACT2 may include a portion more protruding or extending in the opposite direction of the second direction DR2 between the channel area of the first sub-transistor T11-1 and the channel area of the second sub-transistor T11-2. That is, the capacity of the first capacitor C1 may be adjusted by increasing or reducing the mentioned portion of the second semiconductor pattern ACT2.

For example, compared to the one or more embodiments corresponding to FIG. 14B, as illustrated in FIG. 16A, the third semiconductor pattern ACT3 may not include a portion protruding or extending in the opposite direction of the first direction DR1 between the channel area of the third sub-transistor T9-1 and the channel area of the fourth sub-transistor T9-2. As another example, compared to the one or more embodiments corresponding to FIG. 14B, as illustrated in FIG. 16B, the third semiconductor pattern ACT3 may include include a portion more protruding or extending in the opposite direction of the first direction DR1 between the channel area of the third sub-transistor T9-1 and the channel area of the fourth sub-transistor T9-2. That is, the capacity of the second capacitor C2 may be adjusted by increasing or reducing the mentioned portion of the third semiconductor pattern ACT3.

Meanwhile, it has been described with reference to FIG. 16A and FIG. 16B that the protruding portion of the second semiconductor pattern ACT2 and/or the third semiconductor pattern ACT3 is adjusted, but the present disclosure is not limited thereto. For example, the capacity of the first capacitor C1 may be adjusted by adjusting the area or shape of the sixth capacitor electrode CE6 overlapping the second semiconductor pattern ACT2. Similarly, the capacity of the second capacitor C2 may be adjusted by adjusting the area or shape of the fifth capacitor electrode CE5 overlapping the third semiconductor pattern ACT3.

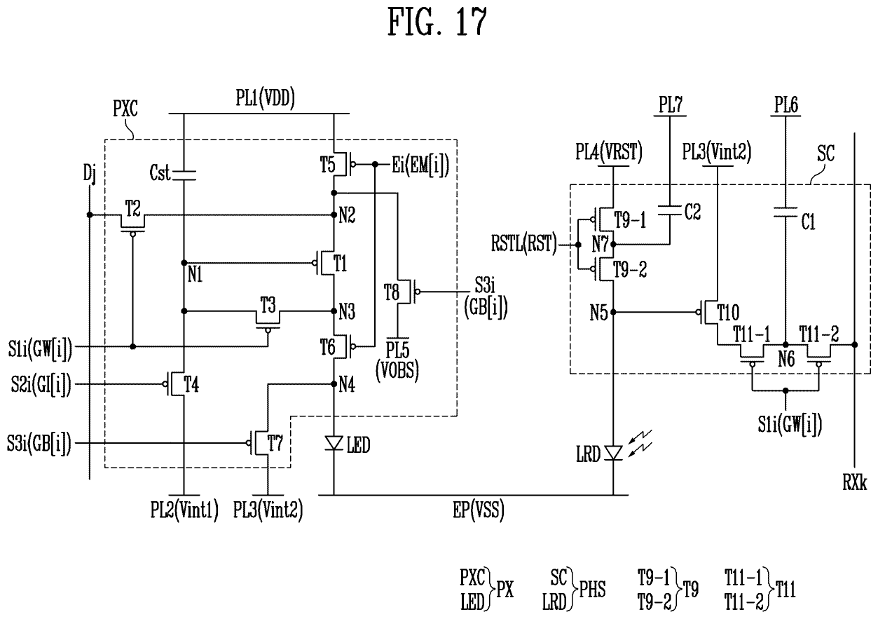

FIG. 17 illustrates a circuit diagram of one or more other embodiments of a pixel and a photo sensor included in the display area of FIG. 4.

Referring to FIG. 13 and FIG. 17, except for the sixth power line PL6 and the seventh power line PL7, the sensor circuit SC (and the pixel circuit PXC) of FIG. 17 may be substantially the same as or similar to the sensor circuit SC (and the pixel circuit PXC) of FIG. 13. Therefore, redundant descriptions will not be repeated.

The first capacitor C1 may be connected to the sixth power line PL6, and the second capacitor C2 may be connected to the seventh power line PL7.

In some embodiments, the second capacitor C2 and the first capacitor C1 may be connected to the same constant voltage wire or other constant voltage wires.

For example, the sixth power line PL6 and the seventh power line PL7 may be electrically connected or integrally formed. As described with reference to FIG. 5, FIG. 10, and FIG. 12, the first capacitor C1 may be connected to the third power line PL3, the fourth power line PL4, or the fifth power line PL5, and similar to the first capacitor C1, the second capacitor C2 may be connected to the third power line PL3, the fourth power line PL4, or the fifth power line PL5. That is, the sixth power line PL6 and the seventh power line PL7 may be connected to or integrally formed with the third power line PL3, the fourth power line PL4, or the fifth power line PL5.

As another example, the sixth power line PL6 and the seventh power line PL7 may be electrically separated. As described with reference to FIG. 5, FIG. 10, FIG. 12, and FIG. 13, the first capacitor C1 may be connected to one of the first power line PL1, the third power line PL3, the fourth power line PL4, and the fifth power line PL5, and the second capacitor C2 may be connected to another one of the first power line PL1, the third power line PL3, the fourth power line PL4, and the fifth power line PL5.

That is, the constant voltage wires to which the first capacitor C1 and the second capacitor C2 are connected are not limited to specific wires.

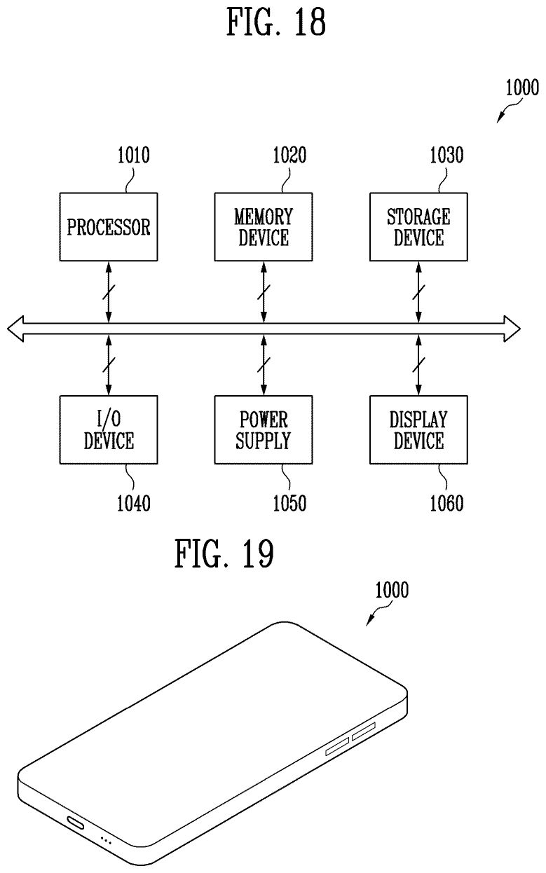

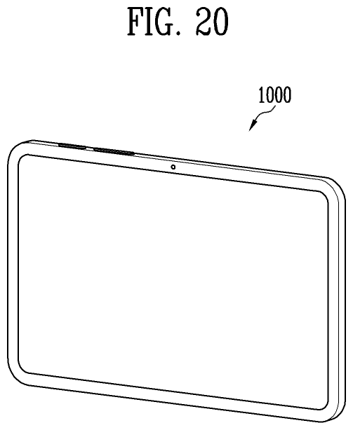

FIG. 18 illustrates a block diagram of an electronic device according to embodiments. FIG. 19 illustrates an example in which the electronic device of FIG. 18 is implemented as a smart phone. FIG. 20 illustrates an example in which the electronic device of FIG. 18 is implemented as a tablet PC.

Referring to FIG. 18 to FIG. 20, an electronic device 1000 may include a processor 1010, a memory device 1020, a storage device 1030, an input/output device 1040, a power supply 1050, and a display device 1060. In this case, the display device 1060 may be the display device 10 of FIG. 1. In addition, the electronic device 1000 may further include several ports capable of communicating with a video card, a sound card, a memory card, a USB device, and the like, or communicating with other systems. As shown in FIG. 19, the electronic device 1000 may be implemented as a smart phone. In one or more other embodiments, as shown in FIG. 20, the electronic device 1000 may be implemented as a tablet PC. However, this is an example, and the electronic device 1000 is not limited thereto. For example, the electronic device 1000 may be implemented as a mobile phone, a video phone, a smart pad, a smart watch, a vehicle navigation, a computer monitor, a laptop, a head mounted display device, or the like.

The processor 1010 may perform corresponding calculations or tasks. In some embodiments, the processor 1010 may be a micro-processor, a central processing unit, an application processor, or the like. The processor 1010 may be connected to other constituent elements through an address bus, a control bus, and a data bus. In some embodiments, the processor 1010 may also be connected to an extension bus, such as a peripheral component interconnect (PCI) bus.

The memory device 1020 may store data necessary for operations of the electronic device 1000. For example, the memory device 1020 may include non-volatile memory devices, such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, and a ferroelectric random access memory (FRAM) device, and/or volatile memory devices, such as a dynamic random access memory (DRAM) device, a static random access memory (SRAM) device, and a mobile DRAM device.

The storage device 1030 may include a solid state drive (SSD), a hard disk drive (HDD), a CD-ROM, and the like.

The input/output device 1040 may include input devices, such as a keyboard, a keypad, a touch pad, a touchscreen, mouse, and the like, and output devices, such as a speaker, a printer, and the like. In some embodiments, the display device 1060 may be included in the input/output device 1040.

The power supply 1050 (or power supply device) may supply power necessary for the operation of the electronic device 1000. For example, the power supply 1050 may be a power management integrated circuit (PMIC).

The display device 1060 may display an image corresponding to visual information of the electronic device 1000. In this case, the display device 1060 may be an organic light-emitting display device or a quantum dot light-emitting display device, but is not limited thereto. The display device 1060 may be connected to other constituent elements through the buses or other communication links.

The technical idea of the present disclosure has been specifically described according to the preferred embodiments, but it should be noted that the foregoing embodiments are provided only for illustration while not limiting the present disclosure. In addition, it will be understood by those skilled in the art that various changes in form and details may be made therein without departing from the scope of the present disclosure.

what is claimed is:

1. A display device comprising:
a pixel comprising a light-emitting element; and
a photo sensor comprising:
a light-receiving element at a same layer as the light-emitting element;
a first sensor transistor configured to control a current flowing to a readout line in response to a voltage of one electrode of the light-receiving element;
a second sensor transistor electrically connected between the first sensor transistor and the readout line, and comprising first and second sub-transistors connected in series; and
a first capacitor between a first middle node, to which the first and second sub-transistors are connected, and a power line.

2. The display device of claim 1, wherein a constant voltage is configured to be applied to the power line.

3. The display device of claim 1, wherein the pixel further comprises a switching transistor electrically connected between the power line and an anode electrode of the light-emitting element.

4. The display device of claim 1, wherein the pixel further comprises
a first transistor electrically connected between a first power line and the light-emitting element; and
a second transistor electrically connected between a data line and the first transistor, and
wherein a gate electrode of the second transistor and a gate electrode of the first sensor transistor are electrically connected to a first scan line.

5. The display device of claim 1, wherein, in a cross-sectional view, the photo sensor further comprises
a semiconductor layer of the first and second sub-transistors;
a gate electrode above the semiconductor layer;
an insulating layer covering the gate electrode;
a capacitor electrode above the insulating layer; and
at least one insulating layer above the capacitor electrode,
wherein the power line is above the at least one insulating layer, and contacts the capacitor electrode through a contact hole, and
wherein the first capacitor comprises the capacitor electrode and the semiconductor layer.

6. The display device of claim 5, wherein, in a plan view, the power line extends in a first direction between the first sensor transistor and the second sensor transistor, and partially protrudes in a second direction to overlap the capacitor electrode.

7. The display device of claim 1, wherein the photo sensor further comprises a third sensor transistor electrically connected between a reference power line and the one electrode of the light-receiving element.

8. The display device of claim 7, wherein the first sensor transistor and the second sensor transistor comprise a silicon semiconductor, and
wherein the third sensor transistor comprises an oxide semiconductor.

9. The display device of claim 7, wherein one electrode of the first sensor transistor is electrically connected to the power line, and
wherein the power line and the reference power line are configured to receive different voltages.

10. The display device of claim 7, wherein the power line and the reference power line are configured to receive a same voltage.

11. The display device of claim 1, wherein the light-emitting element is electrically connected between a first power line and a second power line, and
wherein the power line is configured to receive a same voltage as the first power line or the second power line.

12. The display device of claim 1, wherein the photo sensor further comprises
a third sensor transistor that is electrically connected between a reference power line and the one electrode of the light-receiving element and comprises third and fourth sub-transistors connected in series; and
a second capacitor between a second middle node to which the third and fourth sub-transistors are connected and a first power line.

13. The display device of claim 12, wherein the power line and the first power line are configured to receive a same constant voltage.

14. The display device of claim 13, wherein the pixel further comprises
a first transistor connected between the first power line and the light-emitting element; and
a storage capacitor electrically connected between a gate electrode of the first transistor and the first power line, and
wherein one electrode of the second capacitor and one electrode of the storage capacitor are integral.

15. The display device of claim 14, wherein, in a plan view, the one electrode of the storage capacitor overlaps a first semiconductor pattern of the first transistor, and
wherein the one electrode of the second capacitor has a size that is smaller than that of the one electrode of the storage capacitor, and protrudes from the one electrode of the storage capacitor to overlap a third semiconductor pattern of the third sensor transistor.

16. The display device of claim 14, wherein the pixel further comprises a third transistor electrically connected between one electrode and a gate electrode of the first transistor, and
wherein, in a plan view, one electrode of the first capacitor overlaps a second semiconductor pattern of the second sensor transistor, and protrudes toward the third transistor to overlap a semiconductor pattern of the third transistor.

17. A display device comprising:
a pixel comprising a light-emitting element; and
a photo sensor comprising:
a light-receiving element at a same layer as the light-emitting element;
a first sensor transistor configured to control a current flowing to a readout line in response to a voltage of one electrode of the light-receiving element;
a second sensor transistor electrically connected between the first sensor transistor and the readout line;
a third sensor transistor electrically connected between a reference power line and the one electrode of the light-receiving element, and comprising third and fourth sub-transistors connected in series; and
a second capacitor between a second middle node, to which the third and fourth sub-transistors are connected, and a first power line.

18. The display device of claim 17, wherein the power line and the first power line are configured to receive a same constant voltage.

19. The display device of claim 18, wherein the pixel further comprises
a first transistor connected between the first power line and the light-emitting element; and
a storage capacitor electrically connected between a gate electrode of the first transistor and the first power line, and
wherein one electrode of the second capacitor and one electrode of the storage capacitor are integral.

20. An electronic device comprising:
a processor configure to provide input image data to a display device configured to display an image based on the input image data; and
a power supply configured to supply power to the display device,
wherein the display device comprises
a pixel comprising a light-emitting element; and
a photo sensor comprising a light-receiving element at a same layer as the light-emitting element, and comprising:
a first sensor transistor configured to control a current flowing to a readout line in response to a voltage of one electrode of the light-receiving element;
a second sensor transistor electrically connected between the first sensor transistor and the readout line, and comprising first and second sub-transistors connected in series; and
a first capacitor between a first middle node, to which the first and second sub-transistors are connected, and a power line.
